(19) United States
(12) Patent Application Publication
(10) Pub. No.: US 2025/0277073 A1
(43) Pub. Date: Sep. 4, 2025

(54) CURABLE COMPOSITION, LAMINATE, AND METHOD FOR PRODUCING LAMINATE

(71) Applicant: FUJIFILM Corporation, Tokyo (JP)

(72) Inventor: Hiroaki TSUYAMA, Kanagawa (JP)

(73) Assignee: FUJIFILM Corporation, Tokyo (JP)

(21) Appl. No.: 19/211,268

(22) Filed: May 18, 2025

Related U.S. Application Data
(63) Continuation of application No. PCT/JP2023/043595, filed on Dec. 6, 2023.

(30) Foreign Application Priority Data
Dec. 12, 2022 (JP) 2022-198071

(51) Int. Cl. C08F 220/40; C08F 2/50; C08J 3/24; C08J 7/044; C08J 7/06; C08J 7/18; C08K 5/098; C09D 4/00; C09D 5/00; C09D 11/38; C09D 11/52

(52) U.S. Cl. CPC C08F 220/40; C08F 2/50; C08J 3/247; C08J 7/044; C08J 7/065; C08J 7/18; C08K 5/098; C09D 4/00; C09D 5/00; C09D 11/38; C09D 11/52; C08J 2433/10; C08K 2201/005; C08K 2201/011; C08K 2201/019

(57) ABSTRACT

Provided is a curable composition capable of forming an insulating layer having excellent adhesiveness to a conductive layer and achieving excellent smoothness of the conductive layer at a time of forming the conductive layer on a surface of the insulating layer.

The curable composition is a curable composition for forming an insulating layer adjacent to a conductive layer, the curable composition including a cyclopolymerizable monomer, a thermally crosslinking group-containing monomer, a polyfunctional monomer, a photopolymerization initiator, and a surface modifier including neither a fluorine atom nor a silicon atom.

### CROSS-REFERENCE TO RELATED APPLICATIONS

This application is a Continuation of PCT International Application No. PCT/JP2023/043595 filed on Dec. 6, 2023, which claims priority under 35 U.S.C. § 119 (a) to Japanese Patent Application No. 2022-198071 filed on Dec. 12, 2022. The above applications are hereby expressly incorporated by reference, in their entirety, into the present application.

### BACKGROUND OF THE INVENTION

### 1. Field of the Invention

The present invention relates to a curable composition, a laminate, and a method for producing the laminate.

### 2. Description of the Related Art

A semiconductor device and the like may be interfered by an electromagnetic wave to hinder the normal operation, which may cause malfunction. In addition, in a case where the semiconductor device and the like generate an electromagnetic wave, the electromagnetic wave may interfere with other semiconductor devices and the like or electronic components, which may thus hinder the normal operation.

In order to prevent the interference due to such an electromagnetic wave between electronic components, an electromagnetic wave shield that shields an electromagnetic wave from the outside and an electromagnetic wave generated from a semiconductor device and the like is used. As a technique for forming such an electromagnetic wave shield, for example, a method for forming an electromagnetic wave shield by laminating an insulating layer and a conductive layer on a printed wiring board on which a semiconductor device has been mounted is known.

In order to form the laminate as described above, a method for forming a laminate using an ink jet recording method has been studied from the viewpoint of production advantages such as a possibility of a reduced amount of an ink used and easy adaptation to various shapes.

As the curable composition capable of forming an insulating layer by an ink jet recording method as described above, for example, a curable composition including (A) a photocurable component containing a (meth)acrylic monomer having no hydroxyl group and a (meth)acrylic monomer having a hydroxyl group, (B) a thermosetting component containing an adduct-type blocked isocyanate compound, and (C) a photopolymerization initiator is disclosed in JP2022-007466A.

### SUMMARY OF THE INVENTION

As a result of studying the curable composition disclosed in JP2022-007466A, the present inventors have found that it is difficult to achieve both the adhesiveness between a conductive layer and an insulating layer and the smoothness of the conductive layer in a case where the conductive layer is formed on the insulating layer formed of the curable composition.

In view of the circumstances, an object of the present invention is to provide a curable composition capable of forming an insulating layer having excellent adhesiveness to a conductive layer and achieving excellent smoothness of the conductive layer at a time of forming the conductive layer on a surface of the insulating layer.

In addition, another object of the present invention is to provide a laminate including a conductive layer and an insulating layer formed of the curable composition, and a method for producing the laminate.

As a result of conducting intensive studies on the objects, the present inventors have found that the objects can be accomplished by the following configurations.
[1] A curable composition for forming an insulating layer adjacent to a conductive layer, the curable composition including:
a cyclopolymerizable monomer;
a thermally crosslinking group-containing monomer;
a polyfunctional monomer;
a photopolymerization initiator; and
a surface modifier including neither a fluorine atom nor a silicon atom.
[2] The curable composition according to [1],
in which a mass ratio of a content of the cyclopolymerizable monomer to a content of the thermally crosslinking group-containing monomer is 5.0 to 40.0, and
a mass ratio of the content of the cyclopolymerizable monomer to a content of the polyfunctional monomer is 1.0 to 7.0.
[3] The curable composition according to [1] or [2],
in which the cyclopolymerizable monomer is methyl α-allyloxymethyl acrylate.
[4] The curable composition according to any one of [1] to [3],
in which a content of the thermally crosslinking group-containing monomer is 0.5% by mass or more and less than 5.0% by mass with respect to a total mass of the curable composition.
[5] The curable composition according to any one of [1] to [4],
in which the thermally crosslinking group-containing monomer is a compound represented by Formula (B2) which will be described later.
[6] The curable composition according to any one of [1] to [5],
in which the conductive layer has silver or copper.
[7] A laminate including:
a conductive layer; and
an insulating layer formed of the curable composition according to any one of [1] to [6].
[8] The laminate according to [7],
in which the laminate is used as an electromagnetic wave shield disposed on a printed wiring board.
[9] A method for producing a laminate, the method including:
a step 1 of forming an insulating layer by an ink jet recording method using the curable composition according to any one of [1] to [6]; and
a step 2 of forming a conductive layer on the insulating layer, using a conductive ink.
[10] The method for producing a laminate according to [9],
in which the step 1 includes a step of irradiating a coating film of the curable composition with active energy rays and then heating the coating film.

According to the present invention, it is possible to provide a curable composition capable of forming an insulating layer having excellent adhesiveness to a conductive layer and achieving excellent smoothness of the conductive layer at a time of forming the conductive layer on a surface of the insulating layer.

In addition, according to the present invention, it is also possible to provide a laminate including a conductive layer and an insulating layer formed of the curable composition, and a method for producing the laminate.

### BRIEF DESCRIPTION OF THE DRAWINGS

FIG. 1 is a schematic plan view of an electronic substrate used in Examples.

FIG. 2 is a schematic cross-sectional view taken along a line A-A of FIG. 1.

FIG. 3 is a view showing a state where an insulating layer is formed on the electronic substrate in the schematic cross-sectional view taken along the line A-A of FIG. 1.

FIG. 4 is a view showing a state where an insulating layer and a conductive layer are formed on the electronic substrate in the schematic cross-sectional view taken along the line A-A of FIG. 1.

### DESCRIPTION OF THE PREFERRED EMBODIMENTS

Hereinafter, the present invention will be described in detail.

The following description is made based on representative embodiments of the present invention and the present invention is not limited to such embodiments.

In the present specification, a numerical value range expressed using “to” means a range that includes the preceding and succeeding numerical values of “to” as the lower limit value and the upper limit value, respectively. In a numerical range described in a stepwise manner in the present specification, an upper limit value or a lower limit value described in a certain numerical range may be replaced with an upper limit value or a lower limit value in another numerical range described in a stepwise manner. In addition, in the numerical range described in the present specification, an upper limit value and a lower limit value described in a certain numerical range may be replaced with values shown in Examples.

In the present specification, “(meth)acryl” is a generic term encompassing acryl and methacryl, and means “one or more of acryl and methacryl”. Similarly, a “(meth)acrylate” means “one or more of an acrylate and a methacrylate”, a “(meth)acryloyl group” means “one or more of an acryloyl group and a methacryloyl group”, and an “acrylic resin” means “a polymer having one or more repeating units derived from an acrylate monomer and/or a methacrylate monomer”.

In the present specification, “conductive” means a property of having a volume resistivity of less than 10⁸ Ωcm.

In the present specification, a term “monomer” means a compound having at least one polymerizable group unless otherwise specified.

In the present specification, for each component, one kind of substance corresponding to each component may be used alone, or two or more kinds thereof may be used in combination. Here, in a case where two or more kinds of substances are used for each component, the content of the component indicates a total content of two or more substances unless otherwise specified.

In the present specification, a combination of two or more preferred aspects is a more preferred aspect.

In the present specification, a “step” includes not only an independent step but also a step whose intended purpose is achieved even in a case where the step is not clearly distinguished from other steps.

The bonding direction of the divalent group (for example, —CO—O—) denoted in the present specification is not limited unless otherwise specified. For example, in a case where Y in a compound represented by a formula “X—Y—Z” is —CO—O—, the compound may be any of “X—O—CO—Z” or “X—CO—O—Z”.

### [Curable Composition]

Hereinafter, a curable composition of an embodiment of the present invention (hereinafter also simply referred to as a “curable composition”) will be described in detail.

The curable composition of the embodiment of the present invention includes a cyclopolymerizable monomer, a thermally crosslinking group-containing monomer, a polyfunctional monomer, a photopolymerization initiator, and a surface modifier including neither a fluorine atom nor a silicon atom.

With the curable composition having the configuration, it is possible to form an insulating layer having excellent adhesiveness to a conductive layer and achieving excellent smoothness of the conductive layer at a time of forming a conductive layer on a surface of the insulating layer. A reason for this is not clear in detail, but the present inventors presume it to be as follows.

Furthermore, a mechanism by which the effect is obtained is not limited by the following supposition. In other words, even in a case where an effect is obtained by a mechanism other than the following, it is included in the scope of the present invention.

The curable composition including a cyclopolymerizable monomer, a thermally crosslinking group-containing monomer, a polyfunctional monomer, and a photopolymerization initiator makes it possible to form an insulating layer by a photopolymerization reaction. Further, since the curable composition includes the cyclopolymerizable monomer and the thermally crosslinking group-containing monomer, the insulating layer has excellent adhesiveness to other layers. However, at a time of forming a conductive layer on the insulating layer, at least one of the smoothness of the conductive layer or the adhesiveness between the conductive layer and the insulating layer may not reach a desired level. A reason for this is considered to be as follows: in a case where the curable composition includes a surface modifier including at least one of a silicon atom or a fluorine atom, the wetting property of the insulating layer with respect to the conductive ink for forming the conductive layer is low, the conductive ink is repelled, and a uniform coating film cannot be formed.

The insulating layer formed of the curable composition of the embodiment of the present invention, including a surface modifier including neither silicon nor fluorine, has an excellent surface state and excellent wettability to the conductive ink. As a result, it is presumed that at a time of forming a conductive layer on a surface of the insulating layer formed of the curable composition of the embodiment of the present invention using a conductive ink, the adhesiveness between the conductive layer and the insulating layer is excellent and the smoothness of the conductive layer is excellent.

Hereinafter, the fact that at least one of the adhesiveness between the conductive layer and the insulating layer or the smoothness of the conductive layer is more excellent is also referred to as “the effects of the present invention being more excellent”.

### [Cyclopolymerizable Monomer]

The curable composition includes a cyclopolymerizable monomer.

In a case where the curable composition includes a cyclopolymerizable monomer, the adhesiveness between the conductive layer and the insulating layer and the smoothness of the conductive layer are excellent, and the jetting property of the curable composition by an ink jet recording method or the like is also excellent.

The cyclopolymerizable monomer is a monomer that forms a ring structure in the molecule by a polymerization reaction.

The polymerizable group contained in the cyclopolymerizable monomer is not particularly limited, and may be any of a cationically polymerizable group or a radically polymerizable group. However, the polymerizable group is preferably the radically polymerizable group, and more preferably an ethylenically unsaturated group.

Examples of the ring structure formed by the cyclopolymerizable monomer through a polymerization reaction include an aliphatic hydrocarbon ring and an aliphatic heterocyclic ring, and the ring structure is preferably the aliphatic heterocyclic ring, and more preferably a cyclic ether. In a case where the ring structure formed by the cyclopolymerizable monomer through a polymerization reaction is a cyclic ether, the adhesiveness is more excellent due to the presence of an ether bond, which is a polar group, in the main chain.

The number of ring members in the ring structure is preferably 3 to 8, more preferably 5 or 6, and still more preferably 5.

The cyclopolymerizable monomer is preferably a monomer having two or more ethylenically unsaturated groups in one molecule, in which two ethylenically unsaturated groups are bonded to each other by radical polymerization to form a ring structure in the molecule.

Examples of the cyclopolymerizable monomer include an α-(allyloxymethyl) acrylate, an α-(allyloxymethyl) acrylic acid, and an acrylic ether dimer, and the a-(allyloxymethyl)acrylate is preferable.

Examples of the α-(allyloxymethyl) acrylate include a compound represented by Formula (A1).

The compound represented by Formula (A1) forms a repeating unit represented by Formula (PA1) by a polymerization reaction. The repeating unit represented by Formula (PA1) is a repeating unit having a tetrahydrofuran ring in the main chain.

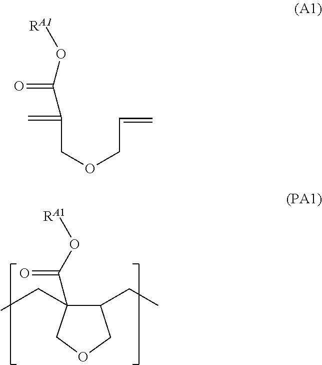

In Formula (A1), R^{A1} represents a monovalent organic group.

Examples of the monovalent organic group include a hydrocarbon group which may have a divalent linking group selected from an ether bond and an amide bond, or may have a substituent.

Examples of the hydrocarbon group include an aliphatic hydrocarbon group and an aromatic hydrocarbon group.

The aliphatic hydrocarbon group may be linear, branched, or cyclic.

The number of carbon atoms in the aliphatic hydrocarbon group is preferably 1 to 30, more preferably 1 to 12, still more preferably 1 to 6, and particularly preferably 1 to 3.

The aromatic hydrocarbon ring may be a monocyclic ring or a polycyclic ring.

The number of carbon atoms in the aromatic hydrocarbon group is preferably 3 to 30, more preferably 6 to 20, and still more preferably 6 to 12.

The expression that the hydrocarbon group may have an ether bond means that the hydrocarbon group may have a divalent linking group represented by-O-between carbon-carbon bonds in the hydrocarbon group. In addition, the expression that the hydrocarbon group may have an amide bond means that the hydrocarbon group may have a divalent linking group represented by —NRCO—. R represents a hydrogen atom or a monovalent hydrocarbon group.

The substituent which may be contained in the hydrocarbon group is not particularly limited, but is preferably a hydroxyl group, an amino group (which may be any of a primary amino group, a secondary amino group, or a tertiary amino group), or a halogen atom.

As R^{A1}, the aliphatic hydrocarbon group is preferable, a linear aliphatic hydrocarbon group having 1 to 6 carbon atoms is more preferable, and a methyl group or an ethyl group is still more preferable.

Examples of the compound represented by Formula (A1) include methyl a-allyloxymethyl acrylate (AOMA), ethyl α-allyloxymethyl acrylate, n-propyl α-allyloxymethyl acrylate, i-propyl α-allyloxymethyl acrylate, n-butyl α-allyloxymethyl acrylate, s-butyl a-allyloxymethyl acrylate, t-butyl α-allyloxymethyl acrylate, n-hexyl α-allyloxymethyl acrylate, 2-ethylhexyl α-allyloxymethyl acrylate, methoxyethyl α-allyloxymethyl acrylate, methoxyethoxyethyl α-allyloxymethyl acrylate, methoxyethoxyethoxyethyl α-allyloxymethyl acrylate, 3-methoxybutyl α-allyloxymethyl acrylate, ethoxyethyl α-allyloxymethyl acrylate, ethoxyethoxyethyl α-allyloxymethyl acrylate, phenoxyethyl α-allyloxymethyl acrylate, phenoxyethoxyethyl α-allyloxymethyl acrylate, hydroxyethyl α-allyloxymethyl acrylate, hydroxypropyl α-allyloxymethyl acrylate, hydroxybutyl α-allyloxymethyl acrylate, 2,3-dihydroxypropyl α-allyloxymethyl acrylate, dimethylaminoethyl α-allyloxymethyl acrylate, diethylaminoethyl α-allyloxymethyl acrylate, acetamidoethyl α-allyloxymethyl acrylate, N-methylacetamidoethyl α-allyloxymethyl acrylate, propionamidoethyl α-allyloxymethyl acrylate, pyrrolidonylethyl α-allyloxymethyl acrylate, cyclohexyl α-allyloxymethyl acrylate, isobornyl α-allyloxymethyl acrylate, tetrahydrofurfuryl α-allyloxymethyl acrylate, tetrahydrofurfuryloxyethyl α-allyloxymethyl acrylate, tetrahydrofurfuryloxyethoxyethyl α-allyloxymethylacrylate, tetrahydropyranyl α-allyloxymethyl acrylate, (5-methyl-5-m-dioxanyl) methyl α-allyloxymethyl acrylate, phenyl α-allyloxymethyl acrylate, benzyl α-allyloxymethyl acrylate, and naphthyl α-allyloxymethyl acrylate.

Among these, AOMA is preferable as the cyclopolymerizable monomer from the viewpoint that the effects of the present invention are more excellent.

As the acrylic ether dimer, an ether dimer of (a-hydroxymethyl) acrylate is preferable.

Examples of the ether dimer of (a-hydroxymethyl) acrylate include a compound represented by Formula (A2).

The compound represented by Formula (A2) forms a repeating unit represented by Formula (PA2) by a polymerization reaction. The repeating unit represented by Formula (PA2) is a repeating unit having a tetrahydropyran ring in the main chain.

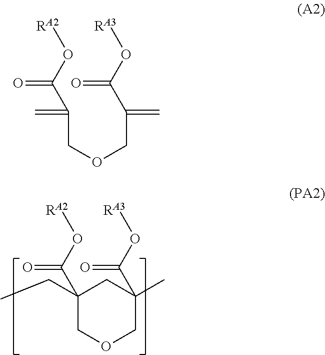

In Formula (A2), R^{A2} and R^{A3} each independently represent a monovalent organic group.

The definition and preferred embodiment of the monovalent organic group represented by R^{A2} and R^{A3} are each the same as those of the monovalent organic group represented by R^{A1} in Formula (A1).

Examples of the compound represented by Formula (A2) include dialkyl-2,2′-(oxydimethylene) diacrylates such as dimethyl-2,2′-[oxybis(methylene)]diacrylate, diethyl-2,2′-[oxybis(methylene)]diacrylate, di(n-propyl)-2,2′-[oxybis(methylene)]diacrylate, di(isopropyl)-2,2′-[oxybis(methylene)]diacrylate, di(n-butyl)-2,2′-[oxybis(methylene)]diacrylate, di(isobutyl)-2,2′-[oxybis(methylene)]diacrylate, di(t-butyl)-2,2′-[oxybis(methylene)]diacrylate, di(t-amyl)-2,2′-[oxybis(methylene)]diacrylate, di(stearyl)-2,2′-[oxybis(methylene)]diacrylate, di(lauryl)-2,2′-[oxybis(methylene)]diacrylate, di(2-ethylhexyl)-2,2′-[oxybis(methylene)]diacrylate, di(1-methoxyethyl)-2,2′-[oxybis(methylene)]diacrylate, di(1-ethoxyethyl)-2,2′-[oxybis(methylene)]diacrylate, dibenzyl-2,2′-[oxybis(methylene)]diacrylate, diphenyl-2,2′-[oxybis(methylene)]diacrylate, dicyclohexyl-2,2′-[oxybis(methylene)]diacrylate, di(t-butylcyclohexyl)-2,2′-[oxybis(methylene)]diacrylate, di(dicyclopentadienyl)-2,2′-[oxybis(methylene)]diacrylate, di(tricyclodecanyl)-2,2′-[oxybis(methylene)]diacrylate, di(isobornyl)-2,2′-[oxybis(methylene)]diacrylate, diadamantyl-2,2′-[oxybis(methylene)]diacrylate, and di(2-methyl-2-adamantyl)-2,2′-[oxybis(methylene)]diacrylate.

Among these, dimethyl-2,2′-[oxybis(methylene)] bisacrylate is preferable as the cyclopolymerizable monomer.

The cyclopolymerizable monomer preferably includes at least one compound selected from the group consisting of a compound represented by Formula (A1) and a compound represented by Formula (A2), more preferably includes the compound represented by Formula (A1), and still more preferably includes AOMA.

In addition, the cyclopolymerizable monomer is preferably the compound represented by Formula (A1), and more preferably AOMA.

The cyclopolymerizable monomer may be used alone or in combination of two or more kinds thereof.

From the viewpoint that the effects of the present invention are more excellent, the content of the cyclopolymerizable monomer is preferably 1.0% to 90.0% by mass, more preferably 5.0% to 80.0% by mass, and still more preferably 20.0% to 70.0% by mass with respect to the total mass of the curable composition.

### [Thermally Crosslinking Group-Containing Monomer]

The curable composition includes a thermally crosslinking group-containing monomer. The thermally crosslinking group-containing monomer is a compound different from the above-described cyclopolymerizable monomer.

In a case where the curable composition includes a thermally crosslinking group-containing monomer, the adhesiveness between the conductive layer and the insulating layer, the crack suppressibility, and the peelability are excellent.

Furthermore, the crack suppressibility means characteristics making it possible to suppress the occurrence of cracks in the insulating layer in a case where the insulating layer is formed using the curable composition. In a case where a laminate consisting of an insulating layer and a conductive layer is used as an electromagnetic wave shield, it is preferable that the laminate has excellent crack suppressibility from the viewpoint that short circuiting between the conductive layer and a wiring line or the like can be prevented and the electromagnetic wave-shielding properties of the laminate are excellent.

In addition, the peelability means ease of peeling of the insulating layer from a base material such as a module in a case where the insulating layer is formed on the base material, using the curable composition. From the viewpoint that the module can be reused by peeling off the insulating layer in the production, it is preferable that the peelability is excellent.

The thermally crosslinking group-containing monomer is a compound having a photopolymerizable group and a thermally crosslinking group in the molecule. Furthermore, the photopolymerizable group and the thermally crosslinking group are groups different from each other.

The photopolymerizable group contained in the thermally crosslinking group-containing monomer is not particularly limited, but is preferably an ethylenically unsaturated group such as a vinyl group, a styryl group, a (meth)acryloxy group, and a (meth)acrylamide group.

The thermally crosslinking group contained in the thermally crosslinking group-containing monomer is a group different from the photopolymerizable group as described above, and is not particularly limited as long as it is a group that undergoes a crosslinking reaction by heat. Examples of the thermally crosslinking group include an epoxy group, an oxetanyl group, an isocyanate group, a blocked isocyanate group, a hydroxyl group, and a leaving group (for example, a halogenated alkyl group). Among these, the epoxy group or the oxetanyl group is preferable, and the epoxy group is more preferable as the thermally crosslinking group from the viewpoint that the effects of the present invention are more excellent.

As the thermally crosslinking group-containing monomer having an epoxy group as the thermally crosslinking group, a compound represented by Formula (B1) is preferable.

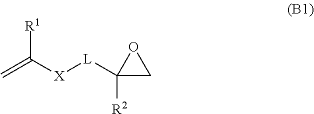

In Formula (B1), R¹ and R² each independently represent a hydrogen atom or an alkyl group.

The alkyl group may be linear, branched, or cyclic.

The number of carbon atoms in the alkyl group is preferably 1 to 12, more preferably 1 to 6, and still more preferably 1 to 3.

As R¹ and R², a hydrogen atom, a methyl group, or an ethyl group is preferable.

In Formula (B1), X represents a single bond, a phenylene group, —COO—, or —CONH—.
X is preferably —COO—.

In Formula (B1), L represents a divalent linking group.

The divalent linking group may have, for example, a substituent, and examples thereof include a divalent hydrocarbon group which may have a divalent linking group selected from —O—, —COO—, and —CONH—.

Examples of the divalent hydrocarbon group include an alkylene group, a divalent aromatic hydrocarbon group, and a group obtained by a combination of these groups.

The alkylene group may be linear, branched, or cyclic, and is preferably linear or branched, and more preferably linear.

The number of carbon atoms in the alkylene group is preferably 1 to 30, more preferably 1 to 10, still more preferably 2 to 8, and particularly preferably 3 to 6.

The divalent aromatic hydrocarbon group may be a monocyclic ring or a polycyclic ring.

The number of carbon atoms in the divalent aromatic hydrocarbon group is preferably 4 to 12, and more preferably 6 to 10.

As the divalent aromatic hydrocarbon group, a phenylene group is preferable.

The substituent which may be contained in the divalent hydrocarbon group is not particularly limited, but is preferably a halogen atom, a hydroxyl group, an alkoxy group, or an acyl group.

The number of divalent linking groups selected from —O—, —COO—, and —CONH— contained in the divalent hydrocarbon group is not particularly limited, but is preferably 1 to 4, more preferably 1 or 2, and still more preferably 1.

The compound represented by Formula (B1) is preferably a compound represented by Formula (B2).

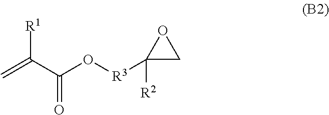

In Formula (B2), R¹ and R² each independently represent a hydrogen atom or an alkyl group.

In Formula (B2), the groups represented by R¹ and R² each have the same definitions as the groups represented by R¹ and R² in Formula (B1).

In Formula (B2), R³ represents an alkylene group which may have an ether bond.

The expression, “may have an ether bond” means that the divalent alkylene group may have a divalent linking group represented by —O— between carbon-carbon bonds in the divalent alkylene group.

The alkylene group may be linear, branched, or cyclic, but is preferably linear or branched, and more preferably linear.

From the viewpoint that the adhesiveness between the conductive layer and the insulating layer, the crack suppressibility, and the peelability are more excellent, the number of carbon atoms in the alkylene group is preferably 1 to 10, more preferably 2 to 8, and still more preferably 3 to 6.

In a case where the alkylene group has an ether bond, the number of ether bonds is not particularly limited, but is preferably 1 to 3, and more preferably 1.

R³ is preferably an alkylene group or a group represented by *^{O}-alkylene group-O-methylene group-*^{E}. *^{O} represents a bonding position between R³ and an oxygen atom adjacent thereto in Formula (B2), and *^{E} represents a bonding position with the other epoxy group. The compound in which R³ is a group represented by *^{O}-alkylene group-O-methylene group-*^{E} represents a compound having an epoxy group as a glycidyl ether group. The number of carbon atoms in the alkylene group in the group represented by *^{O}-alkylene group-O-methylene group-*^{E} is preferably 1 to 10, and more preferably 2 to 8. In addition, the alkylene group in the group represented by *^{O}-alkylene group-O-methylene group-*^{E} is preferably linear.

Examples of the thermally crosslinking group-containing monomer having an epoxy group as the thermally crosslinking group include an epoxyalkyl (meth)acrylate, a monoglycidyl ether mono(meth)acrylate of a diol, a reaction product of glycidol and a (meth)acrylate-containing isocyanate, a vinylbenzyl glycidyl ether, an epoxy group-containing (meth)acrylamide, a 1:1 addition reaction product of a diglycidyl ether and a (meth)acrylic acid, and a monoglycidyl ester mono(meth)acryloxyethyl ester of a dicarboxylic acid. The epoxyalkyl (meth)acrylate or the monoglycidyl ether mono(meth)acrylate of a diol is preferable, and the monoglycidyl ether mono(meth)acrylate of a diol is more preferable.

Specific examples of the epoxyalkyl (meth)acrylate include glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 10,11-epoxyundecyl (meth)acrylate, and 4-glycidylcyclohexyl (meth)acrylate.

Examples of the diol in the monoglycidyl ether mono(meth)acrylate of a diol include ethylene glycol, propylene glycol, tetramethylene glycol, diethylene glycol, triethylene glycol, polyethylene glycol, dipropylene glycol, ditetramethylene glycol, and bisphenol A.

Specific examples of the monoglycidyl ether mono(meth)acrylate of a diol include 4-hydroxybutyl (meth)acrylate glycidyl ether, 2-hydroxyethyl (meth)acrylate glycidyl ether, 3-hydroxypropyl (meth)acrylate glycidyl ether, 6-hydroxyhexyl (meth)acrylate glycidyl ether, and 8-hydroxyoctyl (meth)acrylate glycidyl ether.

Examples of the (meth)acrylate-containing isocyanate in the reaction product of a glycidol and a (meth)acrylate-containing isocyanate include 2-methacryloyloxyethyl isocyanate, 2-acryloyloxyethyl isocyanate, 1,1-(bisacryloyloxymethyl) ethyl isocyanate, and (isocyanatoethyloxy)ethyl methacrylate.

Examples of the vinylbenzyl glycidyl ether include the compounds described in JP1997-227540A (JP-H09-227540A).

Examples of the epoxy group-containing (meth)acrylamide include the compounds described in JP2015-229633A.

Examples of the diglycidyl ether in the 1:1 adduct of a diglycidyl ether and a (meth)acrylic acid include bisphenol A diglycidyl ether, ethylene glycol diglycidyl ether, propylene glycol diglycidyl ether, tetramethylene glycol diglycidyl ether, and diethylene glycol diglycidyl ether.

Examples of the dicarboxylic acid in the monoglycidyl ester mono(meth)acryloyl ester of a dicarboxylic acid include phthalic acid, cyclohexenedicarboxylic acid, cyclohexanedicarboxylic acid, maleic acid, malonic acid, and succinic acid.

Examples of the thermally crosslinking group-containing monomer having an epoxy group as the thermally crosslinking group other than those described above include 1-chloro-2,3-epoxypropyl acrylate, 1-chloro-2,3-epoxypropyl methacrylate, 2-bromo-3,4-epoxybutyl acrylate, 2-bromo-3,4-epoxybutyl methacrylate, 2-(3,4-epoxybutyloxy)-ethyl acrylate, and 2-(3,4-epoxybutyloxy)-ethyl methacrylate.

Among these, as the thermally crosslinking group-containing monomer, glycidyl (meth)acrylate, 4-hydroxybutyl (meth)acrylate glycidyl ether, or 3,4-epoxycyclohexylmethyl (meth)acrylate is preferable, and 4-hydroxybutyl acrylate glycidyl ether is more preferable.

Examples of the thermally crosslinking group-containing monomer having an oxetanyl group as the thermally crosslinking group include (3-ethyloxetan-3-yl) methyl acrylate.

Examples of the thermally crosslinking group-containing monomer having an isocyanate group as the thermally crosslinking group include (meth)acrylic acid derivatives such as 2-(meth)acryloyloxyethyl isocyanate, 3-(meth)acryloyloxypropyl isocyanate, 4-(meth)acryloyloxybutyl isocyanate, 6-(meth)acryloyloxyhexyl isocyanate, 8-(meth)acryloyloxyoctyl isocyanate, and 10-(meth)acryloyloxydecyl isocyanate; and 1,1-(bisacryloyloxymethyl) ethyl isocyanate, and (isocyanatoethyloxy)ethyl methacrylate.

Examples of a leaving group in the thermally crosslinking group-containing monomer having the leaving group as the thermally crosslinking group include a halogen atom and a tosyl group.

Specific examples of the thermally crosslinking group-containing monomer having a leaving group as the thermally crosslinking group include 2-iodoethyl (meth)acrylate, 2-bromoethyl (meth)acrylate, 2-chloroethyl (meth)acrylate, 2-tosylethyl (meth)acrylate, 4-iodobutyl (meth)acrylate, 4-bromobutyl (meth)acrylate, 4-chlorobutyl (meth)acrylate, and 4-tosylbutyl (meth)acrylate.

Examples of the thermally crosslinking group-containing monomer having a hydroxyl group as the thermally crosslinking group include mono(meth)acrylate of a diol. Examples of the diol include bisphenol A, ethylene glycol, propylene glycol, tetramethylene glycol, diethylene glycol, dipropylene glycol, ditetramethylene glycol, and polyethylene glycol.

In addition to those described above, an unsaturated fatty acid hydroxyalkyl ester-modified &-caprolactone can also be used, and examples of a commercially available product thereof include PLACCEL FAI, PLACCEL FMI, PLACCEL FA2D, PLACCEL FM2D, PLACCEL FA5, PLACCEL FM5, and PLACCEL FA10L (all manufactured by Daicel Corporation).

Specific examples of the thermally crosslinking group-containing monomer having a hydroxyl group as the thermally crosslinking group include 2-hydroxyethyl (meth)acrylate, 3-hydroxypropyl (meth)acrylate, 4-hydroxybutyl (meth)acrylate, 2-hydroxypropyl (meth)acrylate, 2-hydroxybutyl (meth)acrylate, and 2-hydroxy-3-phenoxypropyl acrylate.

The thermally crosslinking group-containing monomer may be used alone or in combination of two or more kinds thereof.

In a case where the curable composition includes a monomer containing a thermally crosslinking group having a hydroxyl group, an isocyanate group, a blocked isocyanate group, or a leaving group as the thermally crosslinking group, it is preferable that the curable composition further includes a compound having two or more groups that react with the thermally crosslinking group (for example, a thermally crosslinking agent which will be described later).

From the viewpoint that the adhesiveness between the conductive layer and the insulating layer, and the crack suppressibility are more excellent, the content of the thermally crosslinking group-containing monomer is preferably 0.1% by mass or more, more preferably 0.5% by mass or more, and still more preferably 1.0% by mass or more with respect to the total mass of the curable composition. From the viewpoint that the adhesiveness between the conductive layer and the insulating layer is more excellent, the upper limit is preferably 30.0% by mass or less, more preferably 20.0% by mass or less, still more preferably less than 5.0% by mass, and particularly preferably 3.0% by mass or less.

From the viewpoint that the adhesiveness between the conductive layer and the insulating layer is more excellent, the mass ratio of the content of the cyclopolymerizable monomer to the content of the thermally crosslinking group-containing monomer is preferably 1.0 or more, more preferably 2.0 or more, and still more preferably 5.0 or more. From the viewpoint that the adhesiveness between the conductive layer and the insulating layer, the crack suppressibility, and the smoothness of peelability are more excellent, the upper limit is preferably 100.0 or less, more preferably 80.0 or less, and still more preferably 40.0 or less.

### [Polyfunctional Monomer]

The curable composition of the embodiment of the present invention includes a polyfunctional monomer. The polyfunctional monomer is a compound different from the cyclopolymerizable monomer and the thermally crosslinking group-containing monomer.

The curable composition includes a polyfunctional monomer, and thus, has excellent curing properties as well as excellent smoothness, crack suppressibility, and peelability of the conductive layer.

The polyfunctional monomer is a monomer having two or more polymerizable groups in one molecule.

From the viewpoint that the curing properties are more excellent, the polyfunctional monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate and a polyfunctional vinyl ether, and the polyfunctional (meth)acrylate is preferable.

Examples of the polyfunctional (meth)acrylate include ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, butylene glycol di(meth)acrylate, tetraethylene glycol di(meth)acrylate, neopentyl glycol di(meth)acrylate, 3-methyl-1,5-pentanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate, EO-modified hexanediol di(meth)acrylate, PO-modified hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, tricyclodecanedimethanol di(meth)acrylate, trimethylolethane tri(meth)acrylate, trimethylolpropane tri(meth)acrylate, trimethylolpropane EO-added tri(meth)acrylate, pentaerythritol tri(meth)acrylate, pentaerythritol tetra(meth)acrylate, dipentaerythritol tetra(meth)acrylate, dipentaerythritol penta(meth)acrylate, dipentaerythritol hexa(meth)acrylate, tri(meth)acryloyloxyethoxytrimethylolpropane, glycerin polyglycidyl ether poly(meth)acrylate, and tris(2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether, bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

Among these, as the polyfunctional monomer, polyethylene glycol di(meth)acrylate, 1,6-hexanediol di(meth)acrylate, dipropylene glycol di(meth)acrylate, or 1,4-butanediol di(meth)acrylate is preferable, and polyethylene glycol di(meth)acrylate (EO chain n=4 to 14) or 1,6-hexanediol di(meth)acrylate is more preferable.

The polyfunctional monomer may be used alone or in combination of two or more kinds thereof.

From the viewpoint that the smoothness and the peelability of the conductive layer are more excellent, the content of the polyfunctional monomer is preferably 1.0% to 90.0% by mass, more preferably 5.0% to 80.0% by mass, and still more preferably 10.0% to 60.0% by mass with respect to the total mass of the curable composition.

From the viewpoint that the adhesiveness between the conductive layer and the insulating layer is more excellent, the mass ratio of the content of the cyclopolymerizable monomer to the content of the polyfunctional monomer is preferably 0.05 or more, more preferably 0.2 or more, and still more preferably 1.0 or more. From the viewpoint that the crack suppressibility and the peelability are more excellent, the upper limit is preferably 15.0 or less, more preferably 12.0 or less, and still more preferably 7.0 or less.

From the viewpoint that the effects of the present invention are more excellent, the mass ratio of the content of the polyfunctional monomer to the content of the thermally crosslinking group-containing monomer is preferably 0.1 to 100.0, more preferably 1.0 to 80.0, still more preferably 5.0 to 50.0, and particularly preferably 10.0 to 35.0.

### [Photopolymerization Initiator]

The curable composition includes a photopolymerization initiator.

In a case where the curable composition includes a photopolymerization initiator, the curable composition has excellent curing properties due to a photopolymerization reaction.

The photopolymerization initiator is not particularly limited as long as it is a compound capable of polymerizing monomers (for example, the above-described cyclopolymerizable monomers, polyfunctional monomers, and thermally crosslinking group-containing monomers) by irradiation with actinic rays such as ultraviolet rays, electron beams, and chemical rays, and a known photopolymerization initiator can be used.

Examples of the photopolymerization initiator include a photoradical polymerization initiator and a photocationic polymerization initiator, and the photoradical polymerization initiator is preferable.

Examples of the photopolymerization initiator include an alkylphenone compound, a thioxanthone compound, an oxime compound, an aromatic onium salt compound, an organic peroxide, a hexaarylbisimidazole compound, a borate compound, an azinium compound, a titanocene compound, an active ester compound, a carbon-halogen bond-containing compound, and an alkylamine.

Among these, from the viewpoint of electromagnetic wave-shielding properties, the photopolymerization initiator preferably includes at least one selected from the alkylphenone compound or the thioxanthone compound, and more preferably includes the alkylphenone compound and the thioxanthone compound.

Examples of the alkylphenone compound include an α-hydroxyalkylphenone compound, an α-aminoalkylphenone compound, and a benzyl ketal alkylphenone compound.

Examples of the α-hydroxyalkylphenone compound include 2,2′-dihydroxy-2,2′-dimethyl-1,1′-[methylenebis (4,1-phenylene)]bis(propan-1-one), 1-[4-(2-hydroxyethoxy)phenyl]-2-methyl-2-hydroxy-1-propanone, 2-hydroxy-2-methyl-1-phenylpropan-1-one, and 1-hydroxycyclohexylphenylketone.

Examples of the α-aminoalkylphenone compound include 2-dimethylamino-2-(4-methylbenzyl)-1-(4-morpholin-4-yl-phenyl)-butan-1-one, 2-methyl-1-phenyl-2-morpholinopropan-1-one, 2-methyl-1-[4-(hexyl)phenyl]-2-morpholinopropan-1-one, 2-ethyl-2-dimethylamino-1-(4-morpholinophenyl) butan-1-one, 2-benzyl-2-dimethylamino-1-(4-morpholinophenyl)-butan-1-one, 2-methyl-1-[4-(methylthio)phenyl]-2-morpholinopropan-1-one, 2-(dimethylamino)-2-(4-methylbenzyl)-1-(4-morpholinophenyl)-butan-1-one, and 2-(dimethylamino)-2-[(4-methylphenyl)methyl]-1-[4-(4-morpholinyl)phenyl]-butan-1-one.

Examples of the benzyl ketal alkyl phenone compound include 2,2-dimethoxy-2-phenylacetophenone.

Examples of a commercially available product of the alkylphenone compound include Omnirad 379, Omnirad 651, Omnirad 184, Omnirad 1173, Omnirad 2959, Omnirad 127, Omnirad 907, Omnirad 369, and Omnirad 369E (all manufactured by IGM Resins B. V.).

Examples of the thioxanthone compound include thioxanthone, 2-isopropylthioxanthone, 4-isopropylthioxanthone, 2-chlorothioxanthone, 2,4-dichlorothioxanthone, 2-dodecylthioxanthone, 2,4-diethylthioxanthone, 2,4-dimethylthioxanthone, 1-methoxycarbonylthioxanthone, 2-ethoxycarbonylthioxanthone, 3-(2-methoxyethoxycarbonyl)thioxanthone, 4-butoxycarbonylthioxanthone, 3-butoxycarbonyl-7-methylthioxanthone, 1-cyano-3-chlorothioxanthone, 1-ethoxycarbonyl-3-chlorothioxanthone, 1-ethoxycarbonyl-3-ethoxythioxanthone, 1-ethoxycarbonyl-3-aminothioxanthone, 1-ethoxycarbonyl-3-phenylsulfylthioxanthone, 3,4-di[2-(2-methoxyethoxy)ethoxycarbonyl] thioxanthone, 1-ethoxycarbonyl-3-(1-methyl-1-morpholinoethyl)thioxanthone, 2-methyl-6-dimethoxymethylthioxanthone, 2-methyl-6-(1,1-dimethoxybenzyl)thioxanthone, 2-morpholinomethylthioxanthone, 2-methyl-6-morpholinomethylthioxanthone, n-allylthioxanthone-3,4-dicarboxyimide, n-octylthioxanthone-3,4-dicarboxyimide, N-(1,1,3,3-tetramethylbutyl) thioxanthone-3,4-dicarboxyimide, 1-phenoxythioxanthone, 6-ethoxycarbonyl-2-methoxythioxanthone, 6-ethoxycarbonyl-2-methylthioxanthone, thioxanthone-2-polyethylene glycol ester, and 2-hydroxy-3-(3,4-dimethyl-9-oxo-9H-thioxanthone-2-yloxy)-N,N,N-trimethyl-1-propaneaminium chloride.

Examples of a commercially available product of the thioxanthone compound include SPEEDCURE series (for example, SPEEDCURE ITX, SPEEDCURE 7010, and SPEEDCURE CPTX) manufactured by Lambson.

The photopolymerization initiator may be used alone or in combination of two or more kinds thereof, and it is preferable that two or more kinds of the photopolymerization initiators are used in combination.

In a case where the photopolymerization initiator includes an alkylphenone compound and a thioxanthone compound, the mass ratio of the content of the alkylphenone compound to the content of the thioxanthone compound is preferably 0.1 to 3.0, more preferably 0.1 to 2.0, and still more preferably 0.3 to 1.5 from the viewpoint that the effects of the present invention are more excellent.

The content of the photopolymerization initiator is preferably 0.5% to 20.0% by mass, and more preferably 5.0% to 15.0% by mass with respect to the total mass of the curable composition.

### [Surface Modifier Including Neither Fluorine Atom Nor Silicon Atom]

The curable composition includes a surface modifier including neither a fluorine atom nor a silicon atom.

In a case where the curable composition includes a surface modifier including neither a fluorine atom nor a silicon atom, the adhesiveness between the conductive layer and the insulating layer and the smoothness of the conductive layer are excellent.

The surface modifier is a compound which is present on a surface of the coating film of the curable composition and has a function of controlling the wettability and the leveling properties of the curable composition and the insulating layer formed of the curable composition, but may have a function as an antifoaming agent, a defoaming agent, a foam suppressant, and/or an adhesion promoter.

The surface modifier including neither a fluorine atom nor a silicon atom is also preferably an atom selected from the group consisting of a carbon atom, an oxygen atom, a hydrogen atom, and a nitrogen atom, and more preferably an atom selected from the group consisting of the carbon atom, the oxygen atom, and the hydrogen atom.

It is also preferable that the curable composition does not substantially include a surface modifier including neither silicon atom nor fluorine atom. The expression that the curable composition does not substantially include a surface modifier including neither silicon atom nor fluorine atom means that the content of the surface modifier including a silicon atom or a fluorine atom is 1% by mass or less, preferably 0.1% by mass or less, and more preferably 0.01% by mass or less with respect to the total mass of the surface modifier contained in the curable composition. The lower limit is preferably 0% by mass.

The surface modifier including neither a fluorine atom nor a silicon atom is not limited as long as it does not include a fluorine atom and a silicon atom, and a known surface modifier can be used.

The surface modifier may be a compound comprising a hydrophobic moiety and a hydrophilic moiety.

Examples of the hydrophobic moiety include an aliphatic hydrocarbon group and an aromatic hydrocarbon group.

Examples of the hydrophilic moiety include a hydroxyl group, a carboxy group, a sulfo group, a phosphonic acid group, an amino group, and a quaternary ammonium salt group.

Examples of the surface modifier including neither a fluorine atom nor a silicon atom include a nonionic surface modifier, an anionic surface modifier, and a cationic surface modifier, and the nonionic surface modifier is preferable.

Examples of the nonionic surface modifier including neither a fluorine atom nor a silicon atom include an acrylic surface modifier, a polyether-based surface modifier, and a vinyl-based surface modifier, and an acrylic surface modifier or a polyether-based surface modifier is preferable.

Examples of the acrylic surface modifier include an acrylic resin. The acrylic resin is a polymer including a constitutional unit derived from a (meth)acrylic monomer, and the polymer may be any of a homopolymer or a copolymer.

Examples of the polyether-based surface modifier include polyoxyalkylene glycols such as polyethylene glycol and polypropylene glycol, polyoxyalkylene alkyl ethers such as polyoxyethylene alkyl ether, polyoxyalkylene alkyl ethers such as polyoxyethylene alkyl allyl ether, polyoxyalkylene alkyl phenyl ethers, alkyl polyglycoside, and a polyoxyethylene-polyoxypropylene block copolymer.

Examples of the vinyl-based surface modifier include a surface modifier including a vinyl-based polymer such as polyacetylene, polybutadiene, a polyvinyl ether, and a vinyl ester polymer.

As the nonionic surface modifier other than those described above, for example, a polyoxyalkylene fatty acid ester, acetylene glycol, a mineral oil, a vegetable oil, a fatty acid alcohol, and a fatty acid amide can also be used.

Examples of the anionic surface modifier include a surface modifier having a carboxy group, a surface modifier having a phosphoric acid ester group, a surface modifier having a phosphonic acid group, a surface modifier having a sulfo group, and a surface modifier having a sulfuric acid ester group.

Examples of the cationic surface modifier include a surface modifier having a quaternary ammonium salt group.

The surface modifier including neither a fluorine atom nor a silicon atom may be modified as long as it includes neither a fluorine atom nor a silicon atom. For example, the surface modifier may have a functional group such as an epoxy group and/or a (meth)acryloyl group introduced into a side chain, or may be crosslinked by the functional group. Specifically, for example, the polyether-based surface modifier may be a modified polyether such as polyether-modified (meth)acrylate.

The surface modifier including neither a fluorine atom nor a silicon atom is not particularly limited as long as it includes neither a fluorine atom nor a silicon atom. Specific examples of the surface modifier include BYK-UV-3535, BYK-350, BYK-354, BYK-355/356, BYK-358N/361N, BYK-381, BYK-391, BYK-394, BYK-3441, BYK-399, BYK-3440, BYK-3560, BYK-4500, BYK-4509, BYK-4510, BYK-4512, BYK-4513, BYKETOL-OK, BYK-051N, BYK-052N, BYK-054, BYK-055, BYK-057, BYK-354, BYK-392, BYK-1752, BYK-1759, BYK-1788, BYK-1790, BYK-1791, BYK-1794, BYK-1795, BYK-1797, BYK-1799, and BYK-361N (all manufactured by BYK-Chemie), TEGO Flow 300, TEGO Flow 370, TEGO Flow ZFS 460, TEGO Airex 910, TEGO Airex 920, TEGO Airex 936, and TEGO Airex 966 (all manufactured by Evonik Industries AG), FLOWLEN AC-202, FLOWLEN AC-230, FLOWLEN AC-247, FLOWLEN AC-253, FLOWLEN AC-262H, FLOWLEN AC-265, FLOWLEN AC-300, FLOWLEN AC-300VF, FLOWLEN AC-324, FLOWLEN AC-326F, FLOWLEN AC-380, FLOWLEN AC-1190, FLOWLEN AC-1190HF, and FLOWLEN AC-2300C (all manufactured by Kyoei Chemical Co., Ltd.), and Surfynol 104E, Surfynol 104H, Surfynol 104A, Surfynol 104PA, Surfynol 420, Surfynol 440, Surfynol 465, Surfynol 485, Surfynol DF110D, Surfynol AD01, and Surfynol MD-20 (all manufactured by Nissin Chemical Co., Ltd.).

The surface modifier including neither a fluorine atom nor a silicon atom may be used alone or in combination of two or more kinds thereof.

The content of the surface modifier including neither a fluorine atom nor a silicon atom is preferably 0.001% to 5.0% by mass, more preferably 0.01% to 1.0% by mass, and still more preferably 0.05% to 0.5% by mass with respect to the total mass of the curable composition.

### [Other Components]

The curable composition may include other components other than those described above.

Examples of the other components other than those described above include a monofunctional monomer, a polymerization inhibitor, a thermally crosslinking agent, a thermosetting catalyst, a chain transfer agent, a sensitizer, and an organic solvent.

### <Monofunctional Monomer>

The curable composition may include a monofunctional monomer different from each of the above-described monomers (the cyclopolymerizable monomer, the polyfunctional monomer, and the thermally crosslinking group-containing monomer) as long as the effects of the present invention are not impaired.

The monofunctional monomer is a monomer having only one polymerizable group.

From the viewpoint of the curing properties, the monofunctional monomer is preferably a monofunctional radically polymerizable monomer, and more preferably a monofunctional ethylenically unsaturated monomer.

Examples of the monofunctional ethylenically unsaturated monomer include a monofunctional (meth)acrylate, a monofunctional (meth)acrylamide, a monofunctional aromatic vinyl compound, a monofunctional vinyl ether, and a monofunctional N-vinyl compound, and the monofunctional (meth)acrylate or the monofunctional N-vinyl compound is preferable.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, isostearyl (meth)acrylate, cyclohexyl (meth)acrylate, t-butylcyclohexyl acrylate, 4-n-butylcyclohexyl (meth)acrylate, 4-tert-butylcyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, 3-methoxybutyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate, 2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal (meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid, 2-methacryloyloxyethyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propylene oxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxetanylmethyl) (meth)acrylate, phenoxyethylene glycol (meth)acrylate, 2-carboxyethyl (meth)acrylate, and 2-(meth)acryloyloxyethyl succinate.

From the viewpoint of improving the heat resistance, as the monofunctional (meth)acrylate, a monofunctional (meth)acrylate having an aromatic ring or an aliphatic ring is preferable, and isobornyl (meth)acrylate, 4-tert-butylcyclohexyl (meth)acrylate, dicyclopentenyl (meth)acrylate, or dicyclopentanyl (meth)acrylate is more preferable.

Examples of the monofunctional (meth)acrylamide include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethylstyrene, trimethylstyrene, isopropylstyrene, chloromethylstyrene, methoxystyrene, acetoxystyrene, chlorostyrene, dichlorostyrene, bromostyrene, vinyl benzoic acid methyl ester, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl) styrene, 4-(2-ethylhexyl) styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-ε-caprolactam and N-vinylpyrrolidone.

The monofunctional monomer may be used alone or in combination of two or more kinds thereof.

In a case where the curable composition has a monofunctional monomer, the content of the monofunctional monomer is preferably 1.0% to 40.0% by mass, and more preferably 5.0% to 25.0% by mass with respect to the total mass of the curable composition.

### <Polymerization Inhibitor>

The curable composition preferably includes a polymerization inhibitor.

Examples of the polymerization inhibitor include p-methoxyphenol, quinones (for example, hydroquinone, benzoquinone, and methoxybenzoquinone), phenothiazine, catechols, alkylphenols (for example, dibutyl hydroxy toluene (BHT)), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidin-1-oxyl (TEMPO), 2,2,6,6-tetramethyl-4-hydroxypiperidin-1-oxyl (TEMPOL), and tris (N-nitroso-N-phenylhydroxyamine) aluminum salt (also known as Cupferron Al).

As the polymerization inhibitor, at least one selected from the group consisting of p-methoxyphenol, catechols, quinones, alkylphenols, TEMPO, TEMPOL, and tris (N-nitroso-N-phenylhydroxylamine) aluminum salt is preferable, and at least one selected from the group consisting of p-methoxyphenol, hydroquinone, benzoquinone, BHT, TEMPO, TEMPOL, and tris (N-nitroso-N-phenylhydroxylamine) aluminum salt is more preferable.

The content of the polymerization inhibitor is preferably 0.01% to 5.0% by mass, and more preferably 0.02% to 3.0% by mass with respect to the total mass of the curable composition.

### <Thermally Crosslinking Agent>

The curable composition may include a thermally crosslinking agent. The thermally crosslinking agent is a compound different from the above-described compounds (for example, a cyclopolymerizable monomer, a thermal crosslinkable group-containing monomer, a polyfunctional monomer, and a monofunctional monomer) which can be included in the curable composition.

The thermally crosslinking agent is a compound having two or more thermally crosslinking groups in the molecule.

The thermally crosslinking group is not particularly limited as long as it is a group that undergoes a crosslinking reaction by heating, and examples of the thermally crosslinking group include an epoxy group, an oxetanyl group, an isocyanate group, a blocked isocyanate group, and a hydroxyl group.

As the thermally crosslinking agent, a known thermally crosslinking agent can be used, and examples thereof include an epoxy compound having at least two epoxy groups in the molecule, an oxetane compound having at least two oxetanyl groups in the molecule, a polyisocyanate compound having at least two isocyanate groups in the molecule, a blocked isocyanate compound, and a melamine derivative.

The epoxy compound is a compound having at least two epoxy groups in the molecule and the β-position of the epoxy group may be substituted with an alkyl group.

Specific examples of the epoxy compound include a bisphenol F-type epoxy resin (as a commercially available product thereof, “EPOTOHT YDF-170, manufactured by Tohto Chemical Industry Co., Ltd.”, and the like), a bixylenol-type or biphenol-type epoxy resin or a mixture thereof (as a commercially available product thereof, “YX4000, manufactured by Japan Epoxy Resins Co., Ltd.”, and the like), a heterocyclic epoxy resin having an isocyanurate skeleton (as a commercially available product thereof, “TEPIC, manufactured by Nissan Chemical Industries Ltd.”, “ARALDITE PT810, manufactured by Ciba Specialty Chemicals Inc.”, and the like), a bisphenol A-type epoxy resin, a novolac-type epoxy resin, a hydrogenated bisphenol A-type epoxy resin, a bisphenol S-type epoxy resin, a phenol novolac-type epoxy resin, a cresol novolac-type epoxy resin, a halogenated epoxy resin (for example, a low-brominated epoxy resin, a high-halogenated epoxy resin, and a brominated phenol novolac-type epoxy resin), an allyl group-containing bisphenol A-type epoxy resin, a trisphenol methane-type epoxy resin, a diphenyl dimethanol-type epoxy resin, a phenol biphenylene-type epoxy resin, a dicyclopentadiene-type epoxy resin (as a commercially available product thereof, “HP-720 and HP-7200H, manufactured by DIC Corporation”, and the like), a glycidyl amine-type epoxy resin (for example, a diamino diphenyl methane-type epoxy resin, diglycidyl aniline, and triglycidyl aminophenol), a glycidyl ester-type epoxy resin (for example, a phthalic acid diglycidyl ester, an adipic acid diglycidyl ester, a hexahydrophthalic acid diglycidyl ester, and a dimer acid diglycidyl ester), a hydantoin-type epoxy resin, and an alicyclic epoxy resin (for example, 3,4-epoxycyclohexylmethyl-3′,4′-epoxycyclohexanecarboxylate, bis(3,4-epoxycyclohexylmethyl) adipate, and dicyclopentadiene diepoxide; as a commercially available product thereof, “GT-300, GT-400, and ZEHPE3150, manufactured by Daicel Corporation”, and the like), an imide-type alicyclic epoxy resin, a trihydroxyphenylmethane-type epoxy resin, a bisphenol A novolac-type epoxy resin, a tetraphenylol ethane-type epoxy resin, a glycidyl phthalate resin, a tetraglycidylxylene resin, and a naphthalene group-containing epoxy resin (a naphthol aralkyl-type epoxy resin, a naphthol novolac-type epoxy resin, a tetrafunctional naphthalene-type epoxy resin, and the like; as a commercially available product thereof, “ESN-190 and ESN-360, manufactured by NIPPON STEEL Chemical & Material Co., Ltd.” and “HP-4032, EXA-4750, and EXA-4700, manufactured by DIC Corporation”, and the like), a reaction product of a polyphenol compound obtained by an addition reaction between a phenol compound and a diolefin compound (for example, divinylbenzene and dicyclopentadiene) and epichlorohydrin, a compound obtained by subjecting a ring-opening polymerization polymer of 4-vinylcyclohexene-1-oxide to epoxidization, an epoxy resin having a linear phosphorus-containing structure, an epoxy resin having a cyclic phosphorus-containing structure, an a-methylstyrylbenetype liquid crystal epoxy resin, a dibenzoyloxybenzene-type liquid crystal epoxy resin, an azophenyl-type liquid crystal epoxy resin, an azomethine phenyl-type liquid crystal epoxy resin, a binaphthyl-type liquid crystal epoxy resin, an azine-type epoxy resin, a glycidyl methacrylate copolymer epoxy resin (as a commercially available product thereof, “CP-50S and CP-50M, manufactured by Nippon Oil & Fats Co., Ltd.”, and the like), a cyclohexylmaleimide and glycidyl methacrylate copolymer epoxy resin, a bis (glycidyloxyphenyl) fluorene-type epoxy resin, and a bis (glycidyloxyphenyl) adamantane-type epoxy resin.

The oxetane compound is a compound having at least two oxetanyl groups in the molecule, and specific examples thereof include bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, and 1,4-bis[(3-ethyl-3-oxetanylmethoxy)methyl]benzene.

The polyisocyanate compound is a compound having at least two isocyanate groups in the molecule, and for example, the polyisocyanate compound described in JP1993-009407A (JP-H05-009407A) can be used.

In addition, examples of the polyisocyanate compound include bifunctional isocyanates such as 1,3-phenylene diisocyanate, 1,4-phenylene diisocyanate, 2,4-toluene diisocyanate, 2,6-toluene diisocyanate, 1,3-xylylene diisocyanate, 1,4-xylylene diisocyanate, bis(4-isocyanate-phenyl) methane, bis(4-isocyanate cyclohexyl) methane, isophorone diisocyanate, hexamethylene diisocyanate, and trimethylhexamethylene diisocyanate; an addition reaction product of the bifunctional isocyanate and a polyfunctional alcohol (for example, trimethylolpropane, pentaerythritol, and glycerin) or an alkylene oxide adduct of the polyfunctional alcohol; and cyclic trimers of hexamethylene diisocyanate, hexamethylene-1,6-diisocyanate, and derivatives thereof.

The blocked isocyanate compound is a compound obtained by reacting the polyisocyanate compound with a blocking agent.

Examples of the blocking agent include alcohols such as isopropanol and tert-butanol; lactams such as ε-caprolactam; phenols such as phenol, cresol, p-tert-butylphenol, p-sec-butylphenol, p-sec-amylphenol, p-octylphenol, and p-nonylphenol; heterocyclic hydroxy compounds such as 3-hydroxypyridine and 8-hydroxyquinoline; and active methylene compounds such as dialkylmalonate, methyl ethyl ketoxime, acetylacetone, alkyl acetoacetate oxime, acetoxime, and cyclohexanone oxime.

As the blocked isocyanate compound, the compounds described in JP1994-295060A (JP-H06-295060A) can also be used.

Examples of the melamine derivative include alkylated melamines such as methylol melamine and hexamethylated methylol melamine.

The content of the thermally crosslinking agent is preferably 0.1% to 20.0% by mass, and more preferably 1.0% to 15.0% by mass with respect to the total mass of the curable composition.

### <Thermosetting Catalyst>

The curable composition may include a thermosetting catalyst.

The thermosetting catalyst is a compound having a function of promoting a crosslinking reaction of the thermally crosslinking group included in the thermally crosslinking group-containing monomer.

As the thermosetting catalyst, for example, the compounds described in paragraph [0093] of JP2008-250074A can be used.

### <Chain Transfer Agent>

The curable composition may include a chain transfer agent.

From the viewpoint of improving the reactivity of the photopolymerization reaction, the chain transfer agent is preferably a polyfunctional thiol.

Examples of the polyfunctional thiol include aliphatic thiols, aromatic thiols, poly(mercaptoacetate) of a polyhydric alcohol, poly (3-mercaptopropionate) of a polyhydric alcohol, and poly(mercaptobutyrate).

The content of the chain transfer agent is preferably 0.01% to 20.0% by mass, and more preferably 0.02% to 5.0% by mass with respect to the total mass of the curable composition.

### <Sensitizer>

The curable composition may include a sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine, methylene blue, and toluidine blue), an acridine-based compound (for example, acridine orange, chloroflavine, and acryflavine), anthraquinones (for example, anthraquinone), a squarylium-based compound (for example, squarylium), a coumarin-based compound (for example, 7-diethylamino-4-methylcoumarin), and a thiochromanone-based compound (for example, thiochromanone).

The content of the sensitizer is preferably 1.0% to 15.0% by mass, and more preferably 1.5% to 5.0% by mass with respect to the total mass of the curable composition.

### <Organic Solvent>

The curable composition may include an organic solvent.

Examples of the organic solvent include (poly) alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether; (poly) alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether; (poly) alkylene glycol acetates such as diethylene glycol acetate; (poly) alkylene glycol diacetates such as ethylene glycol diacetate and propylene glycol diacetate; (poly) alkylene glycol monoalkyl ether acetates such as ethylene glycol monobutyl ether acetate and propylene glycol monomethyl ether acetate; ketones such as methyl ethyl ketone and cyclohexanone; lactones such as γ-butyrolactone; esters such as ethyl acetate, propyl acetate, butyl acetate, 3-methoxybutyl acetate (MBA), methyl propionate, and ethyl propionate; cyclic ethers such as tetrahydrofuran and dioxane; and amides such as dimethylformamide and dimethylacetamide.

The content of the organic solvent is preferably 70.0% by mass or less, and more preferably 50.0% by mass or less with respect to the total mass of the curable composition. The lower limit may be 0% by mass with respect to the total mass of the curable composition.

The curable composition may also include additives such as a thermal polymerization initiator, a co-sensitizer, an ultraviolet absorber, an antioxidant, a fading inhibitor, and a basic compound, in addition to those described above.

### [Physical Properties]

The hydrogen ion concentration (pH) of the curable composition is preferably 7 to 10, and more preferably 7.5 to 9.5 from the viewpoint of jetting stability in a case of forming a coating film using an ink jet recording method which will be described later.

The pH is a value measured at 25° C. of a measurement target using a pH meter (for example, pH meter model number “HM-31”, manufactured by DKK-TOA Corporation).

The viscosity of the curable composition is preferably 0.5 to 60 mPa·s, and more preferably 2 to 40 mPa·s. The viscosity is a value at 25° C.

The viscosity is a value measured at 25° C. of a measurement target using a viscometer (for example, a TV-22-type viscometer, manufactured by Toki Sangyo Co., Ltd.).

The surface tension of the curable composition is preferably 60 mN/m or less, more preferably 10 to 50 mN/m, and still more preferably 15 to 45 mN/m.

The surface tension is a value measured at 25° C. of a measurement target using a surface tensiometer (automatic surface tensiometer, product name “CBVP-Z”, manufactured by Kyowa Interface Science Co., Ltd.) according to a plate method.

### [Preparation Method]

As a method for preparing the curable composition, a known method can be used.

Specific examples thereof include a method in which various components included in the curable composition are added in portions or all at once, and the components are stirred using a stirrer (for example, a mixer).

### [Use]

The curable composition is used for forming an insulating layer adjacent to a conductive layer which will be described later.

In other words, the curable composition is used for producing a laminate having a conductive layer and an insulating layer adjacent to the conductive layer. A use of the laminate will be described later.

### [Laminate]

The laminate of an embodiment of the present invention includes a conductive layer and an insulating layer adjacent to the conductive layer.

### [Insulating Layer]

The insulating layer is a layer formed of the above-described curable composition. The insulating layer preferably includes a cured product of the above-described curable composition and/or a decomposition product thereof.

A method for forming the insulating layer will be described later.

The thickness of the insulating layer is not particularly limited and can be appropriately adjusted depending on the use and/or the shape of an object on which the insulating layer is formed. Among these, the thickness of the insulating layer is preferably 0.1 to 1,000 μm, and more preferably 10 to 500 μm.

The thickness of the insulating layer is a value obtained by measuring a level difference between the base material and the insulating layer using a tactile level difference gauge, and calculating an arithmetic mean value of the thicknesses of 10 points measured.

The volume resistivity of the insulating layer is preferably 10¹⁰ Ωcm or more, and more preferably 10¹² Ωcm or more. The upper limit is not particularly limited, but may be 10¹⁶ Ωcm or less.

The volume resistivity of the insulating layer can be measured using a high resistance resistivity meter.

The glass transition temperature (Tg) of the insulating layer is not particularly limited, but in a case where the insulating layer is formed on a substrate having unevenness (for example, a printed wiring board on which an electronic component which will be described later is mounted), the glass transition temperature is preferably 0° C. to 100° C., more preferably 5° C. to 80° C., and still more preferably 10° C. to 60° C.

In a case where the glass transition temperature of the insulating layer satisfies the above-described requirement, the internal stress generated in the insulating layer can be relaxed and the crack suppressibility is excellent, which is thus more preferable.

The glass transition temperature can be measured by a differential scanning calorimeter (for example, a differential scanning calorimeter Q2000, manufactured by TA Instruments).

### [Conductive Layer]

The conductive layer is a layer having conductivity, which is adjacent to the insulating layer. The expression “having conductivity” means that a volume resistivity of the conductive layer is less than 10⁸ Ωcm.

A method of forming the conductive layer will be described later.

The conductive layer is preferably a layer having a metal. Examples of the metal include gold, silver, platinum, palladium, iridium, osmium, ruthenium, rhodium, rhenium, nickel, titanium, cobalt, copper, chromium, manganese, iron, zirconium, tin, tungsten, molybdenum, vanadium, aluminum, magnesium, zinc, and lead.

Among these, from the viewpoint of the conductivity, the conductive layer preferably includes at least one metal selected from the group consisting of gold, silver, copper, platinum, nickel, and palladium, and more preferably includes at least one metal selected from the group consisting of silver and copper.

It is preferable that the conductive layer includes components included in a conductive ink which will be described later and/or decomposition products thereof, and does not include a solvent included in the conductive ink.

The thickness of the conductive layer is not particularly limited and can be appropriately adjusted depending on the use and/or the shape of an object on which the insulating layer is formed. Among these, the thickness of the conductive layer is preferably 0.1 to 100 μm, and more preferably 1 to 50 μm.

The thickness of the conductive layer can be measured by the same method as the thickness of the insulating layer.

The volume resistivity of the conductive layer is less than 10⁸ Ωcm, and preferably 10⁰ Ωcm or less. The lower limit is not particularly limited, but may be 10⁻⁸ Ωcm or more.

The volume resistivity of the conductive layer can be measured using a low resistance resistivity meter.

In the laminate, the ratio of the film thickness of the insulating layer to the film thickness of the conductive layer is preferably 1 to 10,000, more preferably 10 to 5,000, and still more preferably 50 to 2,000.

### [Use]

The use of the laminate is not particularly limited, but examples thereof include an electromagnetic wave shield.

Among these, the laminate is preferably used as an electromagnetic wave shield disposed on a printed wiring board. The printed wiring board refers to a board on which wiring line is formed on at least one of the substrate or the inside of the substrate.

Examples of the printed wiring board include a flexible printed substrate, a rigid printed substrate and a rigid flexible substrate.

Examples of the substrate constituting the printed wiring board include a glass epoxy substrate, a ceramic substrate, a polyimide substrate, and a polyethylene terephthalate substrate. The substrate may have a monolayer structure or a multilayer structure.

The wiring line provided on the printed wiring board is preferably a copper wiring line. For example, one end of the wiring line is connected to an external power supply and the other end is connected to a terminal of the electronic component.

An electronic component may be mounted on the printed wiring board. The electronic component is not particularly limited, and examples thereof include a semiconductor chip, a capacitor, and a transistor.

In a case where the laminate is used as an electromagnetic wave shield disposed on a printed wiring board, it is preferable that the laminate is disposed to cover electronic components that can be mounted on the printed wiring board.

### [Method for Producing Laminate]

The method for producing a laminate of the embodiment of the present invention includes a step 1 of forming an insulating layer by an ink jet recording method using the curable composition, and a step 2 of forming a conductive layer on the insulating layer, using a conductive ink.

### [Step 1]

The step 1 is a step of forming an insulating layer by an ink jet recording method using the curable composition.

The details of the above-described curable composition are as described above.

Hereinafter, each step that can be included in the step 1 will be described in detail.

### <Ink Jet Recording Method>

The ink jet recording method may be any of an electric charge control method of jetting an ink by using electrostatic attraction force, a drop-on-demand method (pressure pulse method) using a vibration pressure of a piezo element, an acoustic ink jet method of jetting an ink by using a radiation pressure by means of converting electric signals into acoustic beams and irradiating the ink with the acoustic beams, or a thermal ink jet (Bubble Jet (registered trademark)) method of forming air bubbles by heating an ink and using the generated pressure.

As the ink jet recording method, the method described in JP1979-059936A (JP-S54-059936A) is preferable, and an ink jet recording method in which an ink subjected to an action of thermal energy undergoes a rapid change in volume and the ink is jetted from a nozzle by an action force caused by this change in state is more preferable.

In addition, examples of the ink jet recording method include the methods described in paragraphs [0093] to [0105] of JP2003-306623A.

Examples of an ink jet head used in the ink jet recording method include an ink jet head for a shuttle method of using short serial heads that are caused to scan a base material in a width direction of the base material to perform recording, and an ink jet head for a line method of using line heads that each consist of recording elements arranged for the entire area of at least one side of a base material.

In the line method, since pattern formation can be performed on the entire surface of a base material by scanning the base material in a direction perpendicular to a direction in which the recording elements are arranged, a transport system such as a carriage that scans a short head is unnecessary.

In addition, since the movement of the carriage and complex scanning control on the base material are not necessary and only the base material moves, it is possible to increase the formation speed, as compared to the shuttle method.

Examples of an ink jet recording device for applying the curable composition using the ink jet recording method include DMP-2850 (manufactured by FUJIFILM Dimatix, Inc.).

The amount of the curable composition jetted from the nozzle of the ink jet head is preferably 1 to 100 pL (picoliters), more preferably 3 to 80 pL, and still more preferably 3 to 20 pL per dot.

### (Base Material)

The curable composition is preferably applied onto a base material by an ink jet recording method.

A material of the base material is not particularly limited and can be selected depending on the purposes. Examples of the material of the base material include synthetic resins such as polyimide, polyethylene terephthalate, polybutylene terephthalate, polytrimethylene terephthalate, polyethylene naphthalate, polybutylene naphthalate, polycarbonate, polyurethane, polypropylene, polyvinyl chloride, polystyrene, polyvinyl acetate, an acrylic resin, an acrylonitrile styrene resin (AS resin), an acrylonitrile-butadiene-styrene copolymer (ABS resin), triacetyl cellulose, polyamide, polyacetal, polyphenylene sulfide, polysulfone, an epoxy resin, a glass epoxy resin (impregnated resin in which an epoxy resin is impregnated into glass fiber), a melamine resin, a phenol resin, a urea resin, an alkyd resin, a fluororesin, and polylactic acid; inorganic materials such as copper, steel, aluminum, silicon, soda glass, alkali-free glass, and indium tin oxide (ITO); and papers such as base paper, art paper, coated paper, cast coated paper, resin coated paper, and synthetic paper.

The base material is preferably a synthetic resin base material such as a glass epoxy resin or polyimide from the viewpoint of the insulating properties and the adhesiveness between the insulating layer and the base material.

The base material may be one layer or two or more layers. In a case where the base material has two or more layers, the materials of the plurality of layers may be the same as or different from each other.

The base material may be a printed wiring board. The details of the printed wiring board are as described above.

The base material is preferably in the form of a sheet or a film.

A thickness of the base material is preferably 20 to 2,000 μm.

The base material may have an ink receiving layer. The ink receiving layer means a coating layer formed on the base material to absorb and fix the ink.

The thickness of the ink receiving layer is preferably 1 to 20 μm from the viewpoint that the homogeneity of the wetting spread of the curable composition is improved.

Before applying the curable composition to the base material, the base material may be subjected to a pretreatment. As the pretreatment, a known method such as an ozone treatment, a plasma treatment, a corona treatment, a primer treatment, and a roughening treatment can be used.

The temperature of the base material in a case of applying the curable composition is preferably 20° C. to 80° C., and more preferably 40° C. to 80° C. In a case where the temperature of the base material is 20° C. to 80° C., the drying of the curable composition can be promoted while suppressing deformation of the base material due to heat.

### <Active Energy Ray Irradiating Step>

The step 1 preferably includes an active energy ray irradiating step of irradiating the coating film of the curable composition formed by the ink jet recording method with active energy rays.

In the active energy ray-irradiating step, examples of the active energy ray include ultraviolet rays (hereinafter also referred to as “UV”), visible rays, and electron beams, and the ultraviolet rays are preferable.

Examples of a light source of the active energy ray include a mercury lamp, a gas laser, a solid-state laser, a mercury lamp, a metal halide lamp, an ultraviolet fluorescent lamp, an ultraviolet-light emitting diode (UV-LED), and an ultraviolet laser diode (UV-LD), and the metal halide lamp, the high-pressure mercury lamp, the medium-pressure mercury lamp, the low-pressure mercury lamp, or the UV-LED is preferable.

The peak wavelength of the active energy ray is preferably 200 to 405 nm, more preferably 250 to 400 nm, and still more preferably 300 to 400 nm.

The illuminance of the active energy ray is preferably 4 W/cm² or more, more preferably 8 W/cm² or more, and still more preferably 10 W/cm² or more. The upper limit is not particularly limited, but is, for example, 20 W/cm².

The exposure amount of the active energy ray is preferably 0.1 to 10 J/cm², and more preferably 0.5 to 7.5 J/cm².

### <Heating Step>

It is preferable that the step 1 further includes a heating step of performing a heating treatment after the active energy ray irradiating step.

The heating method is not particularly limited and a known method can be used.

The heating temperature is preferably 80° C. to 200° C., more preferably 80° C. to 180° C., and still more preferably 80° C. to 160° C.

The heating time is preferably 1 to 180 minutes, and more preferably 1 to 120 minutes.

In the step of producing a laminate, the step 1 may be carried out only once or may be carried out twice or more. In a case where the step 1 is carried out twice or more, the conditions for each time may be the same as or different from each other.

In addition, each step that can be included in the step 1 may be carried out only once or may be carried out twice or more. For example, the active energy ray irradiation step may be carried out twice or more.

Among these, from the viewpoint that an insulating layer having a desired thickness is easily formed, it is preferable that the application of the curable composition by an ink jet recording method and the active energy ray irradiation step are performed as one cycle and the cycle is repeated. Furthermore, it is more preferable that the heating step is carried out after the cycle is repeated to obtain a coating film having a desired thickness.

### [Step 2]

The step 2 is a step of forming a conductive layer on the insulating layer formed in the step 1 using a conductive ink.

Hereinafter, each step that can be included in the step 2 will be described in detail.

### <Application of Conductive Ink>

The step 2 includes a step of applying a conductive ink onto the insulating layer formed in the step 1.

The conductive ink will be described later.

A method for applying the conductive ink is not particularly limited and a known method can be used. Examples thereof include a method of applying a conductive ink and an ink jet recording method.

Among these, the ink jet recording method is preferable from the viewpoint that the thickness of the conductive layer formed by one application can be reduced by jetting a small amount of the composition.

Examples of the ink jet recording method for applying the conductive ink include the ink jet recording method in the above-described step 1.

The temperature of the base material having an insulating layer in a case of applying the conductive ink is preferably 20° C. to 120° C., and more preferably 40° C. to 100° C.

### <Curing Treatment Step>

It is preferable that the step 2 further has a curing treatment step of curing the conductive ink by subjecting the conductive ink applied onto the insulating layer to at least one of a baking treatment or a light irradiation treatment.

In the curing treatment step, only one of the baking treatment or the light irradiation treatment may be performed, or the both may be performed.

The baking temperature in the baking treatment is preferably 80° C. or higher, and more preferably 100° C. or higher. From the viewpoint of reducing a damage to the base material and the like, the upper limit is preferably 250° C. or lower, and more preferably 200° C. or lower.

The baking time in the baking treatment is preferably 1 minute or more. From the viewpoint of reducing a damage to the base material and the like, the upper limit is preferably 120 minutes or less, and more preferably 60 minutes or less.

Examples of the light in the light irradiation treatment include ultraviolet rays and infrared rays.

The peak wavelength of the light is preferably 200 to 405 nm, more preferably 250 to 400 nm, and still more preferably 300 to 400 nm.

An exposure amount in the light irradiation treatment is preferably 0.1 to 10,000 J/cm², and more preferably 1 to 500 J/cm².

From the viewpoint that the conductivity of the conductive layer is more excellent, the time from a time point at which the application of the conductive ink is completed to a start of the baking treatment or the light irradiation treatment is preferably 60 seconds or less. Furthermore, the phrase, “time point at which the application of the conductive ink is completed” refers to a time point at which all the droplets of the conductive ink have been landed on the insulating layer.

In the step of producing a laminate, the step 2 may be carried out only once or may be carried out twice or more. In a case where the step 1 is carried out twice or more, the conditions for each time may be the same as or different from each other.

In addition, each step that can be included in the step 2 may be carried out only once or may be carried out twice or more. For example, the light irradiation treatment may be carried out twice or more.

Among these, from the viewpoint that a conductive layer having a desired thickness is easily formed, it is preferable that the application of the conductive ink and the curing treatment step (preferably the heating treatment) are set as one cycle and the cycle is repeatedly performed.

### [Conductive Ink]

The conductive ink used in the step 2 will be described in detail.

The conductive ink means an ink for forming a conductive layer.

Examples of the conductive ink include an ink including metal particles (hereinafter also referred to as a “metal particle ink”), an ink including a metal complex (hereinafter also referred to as a “metal complex ink”), and an ink including a metal salt (hereinafter also referred to as a “metal salt ink”), and the metal complex ink or the metal salt ink is preferable.

The hydrogen ion concentration (pH) of the conductive ink is preferably 7 to 10, and more preferably 7.5 to 9.5 from the viewpoint of jetting stability.

The pH can be measured by the same method as the pH of the curable composition.

The viscosity of the conductive ink is preferably 1 to 100 mPa·s, more preferably 2 to 50 mPa·s, and still more preferably 3 to 30 mPa·s. The viscosity is a value at 25° C.

The viscosity can be measured by the same method as the viscosity of the curable composition.

The surface tension of the conductive ink is preferably 20 to 45 mN/m, and more preferably 25 to 40 mN/m.

The surface tension can be measured by the same method as the surface tension of the curable composition.

### <Metal Particle Ink>

The metal particle ink is, for example, a conductive ink in which metal particles are dispersed in a dispersion medium.

### (Metal Particles)

The metal particle ink includes metal particles.

Examples of the metal constituting the metal particles include nickel, titanium, cobalt, copper, chromium, manganese, iron, zirconium, tin, tungsten, molybdenum, vanadium, gold, silver, platinum, palladium, iridium, osmium, ruthenium, rhodium, rhenium, and alloys including these metals.

From the viewpoint of the conductivity, the metal constituting the metal particles preferably includes at least one selected from the group consisting of silver, gold, platinum, nickel, palladium, and copper, more preferably includes at least one of silver or copper; and still more preferably includes silver.

In the present invention, the “metal particles” do not include metal oxide particles such as titanium oxide.

From the viewpoint of the process suitability, the pattern formability, and the uniformity of the thickness of the conductive layer, the average primary particle diameter of the metal particles is preferably 10 to 500 nm, and more preferably 10 to 200 nm.

The average primary particle diameter of the metal particles is measured by a laser diffraction/scattering method.

In addition, the metal particle ink may include metal particles having an average primary particle diameter of 500 nm or more, as necessary.

The content of the metal particles in the metal particle ink is preferably 10% to 90% by mass, and more preferably 20% to 50% by mass with respect to the total mass of the metal particle ink. (Dispersant)

The metal particle ink may include a dispersant which adheres to at least a part of a surface of the metal particles. The dispersant substantially constitutes metal colloidal particles, together with the metal particles. The dispersant has an action of coating the metal particles to improve dispersibility of the metal particles and prevent aggregation.

The dispersant is preferably an organic compound capable of forming the metal colloidal particles. From the viewpoint of the conductivity and the dispersion stability, the dispersant is preferably an amine, a carboxylic acid or a salt thereof, an alcohol, or a resin dispersant.

The content of the dispersant in the metal particle ink is preferably 0.5% to 50% by mass, and more preferably 1% to 30% by mass with respect to the total mass of the metal particle ink.

### (Solvent)

The metal particle ink preferably includes a solvent.

The solvent preferably functions as a dispersion medium, and is also preferably a component different from the above-described dispersant.

The type of the solvent is not particularly limited and examples of the solvent include an organic solvent such as a hydrocarbon and an alcohol, and water.

The solvent included in the metal particle ink is preferably volatile. Furthermore, in the present specification, the boiling point means a standard boiling point unless otherwise specified.

From the viewpoint of the stability and the baking properties of the metal particle ink, the boiling point of the solvent is preferably 50° C. to 250° C., more preferably 70° C. to 220° C., and still more preferably 80° C. to 200° C.

The content of the solvent in the metal particle ink is preferably 1% to 50% by mass, more preferably 10% to 45% by mass, and still more preferably 20% to 40% by mass with respect to the total mass of the metal particle ink.

### (Resin)

The metal particle ink may include a resin.

Examples of the resin include polyester, polyurethane, a melamine resin, an acrylic resin, a styrene-based resin, a polyether, and a terpene resin.

### (Thickener)

The metal particle ink may include a thickener.

Examples of the thickener include clay minerals such as clay, bentonite, and hectorite; cellulose derivatives such as methyl cellulose, carboxymethyl cellulose, hydroxyethyl cellulose, hydroxypropyl cellulose, and hydroxypropyl methyl cellulose; and polysaccharides such as xanthan gum and guar gum.

### (Surfactant)

The metal particle ink may include a surfactant from the viewpoint that a uniform coating film is easily formed.

### (Method for Producing Metal Particle Ink)

The metal particles may be a commercially available product or may be produced by a known method.

Examples of a method for producing the metal particles include a wet reduction method, a vapor phase method, and a plasma method, and the wet reduction method capable of producing metal particles having an average particle diameter of 200 nm or less with a narrow particle size distribution is preferable.

In the production of the metal particle ink, a heat treatment may be performed such that the contents of various components included in the metal particle ink are adjusted to be in predetermined ranges. A heat treatment may be performed under reduced pressure or under normal pressure. In a case where the heat treatment is performed under normal pressure, the heat treatment may be performed in the atmospheric air or in an inert gas atmosphere.

### <Metal Complex Ink>

The metal complex ink is, for example, a conductive ink obtained by dissolving a metal complex in a solvent.

### (Metal Complex)

The metal complex ink includes a metal complex.

Examples of a metal constituting the metal complex include silver, copper, gold, aluminum, magnesium, tungsten, molybdenum, zinc, nickel, iron, platinum, tin, copper, and lead, and from the viewpoint of the conductivity, the examples of the metal preferably include at least one selected from the group consisting of silver, gold, platinum, nickel, palladium, and copper, more preferably include at least one of silver or copper, and still more preferably include silver.

The content of the metal in the metal complex ink in terms of metal element is preferably 1% to 40% by mass, more preferably 5% to 30% by mass, and still more preferably 7% to 20% by mass with respect to the total mass of the metal complex ink.

The metal complex can be obtained, for example, by reacting a metal salt with a complexing agent. Examples of a method for producing the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include an oxide, a thiocyanate, a sulfide, a chloride, a cyanide, a cyanate, a carbonate, an acetate, a nitrate, a nitrite, a sulfate, a phosphate, a perchlorate, a tetrafluoroborate, an acetylacetonate complex salt, and a carboxylate of a metal. Furthermore, two or more kinds of the salts may be combined.

Examples of the complexing agent include an amine, an ammonium carbamate-based compound, an ammonium carbonate-based compound, an ammonium bicarbonate compound, and a carboxylic acid, and from the viewpoint of conductivity and stability of a metal complex, at least one selected from the group consisting of an ammonium carbamate-based compound, an ammonium carbonate-based compound, an amine, and a carboxylic acid having 8 to 20 carbon atoms is preferably included.

The metal complex has a structure derived from a complexing agent, and is preferably a metal complex having a structure derived from at least one selected from the group consisting of an ammonium carbamate-based compound, an ammonium carbonate-based compound, an amine, and a carboxylic acid having 8 to 20 carbon atoms.

The content of the metal complex in the metal complex ink is preferably 10% to 90% by mass, and more preferably 10% to 40% by mass with respect to the total mass of the metal complex ink.

### (Solvent)

The metal complex ink preferably includes a solvent.

The solvent is not particularly limited as long as it can dissolve various components such as the metal complex included in the metal complex ink.

From the viewpoint of ease of production, the boiling point of the solvent is preferably 30° C. to 300° C., more preferably 50° C. to 200° C., and still more preferably 50° C. to 150° C.

It is preferable that the solvent is included in the metal complex ink such that the concentration of metal ions with respect to the metal complex (an amount of metals present as liberated ions with respect to 1 g of the metal complex) is 0.01 to 3.6 mmol/g; and it is more preferable that the solvent is included in the metal complex ink such that the concentration of the metal ions with respect to the metal complex is 0.05 to 2 mmol/g. In a case where the concentration of the metal ions is within the range, the metal complex ink has excellent fluidity and exhibits excellent conductivity.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water, and the aromatic hydrocarbon is preferable.

### (Reducing Agent)

The metal complex ink may include a reducing agent.

In a case where the metal complex ink includes a reducing agent, reduction from the metal complex to the metal is promoted.

Examples of the reducing agent include a borohydride metal salt, an aluminum hydride salt, an amine, an alcohol, an organic acid, reduced sugar, a sugar alcohol, sodium sulfite, a hydrazine compound, dextrin, hydroquinone, hydroxylamine, ethylene glycol, glutathione, and an oxime compound.

The content of the reducing agent in the metal complex ink is preferably 0.1% to 20% by mass, more preferably 0.3% to 10% by mass, and still more preferably 1% to 5% by mass with respect to the total mass of the metal complex ink.

### (Resin)

The metal complex ink may include a resin.

In a case where the metal complex ink includes a resin, the adhesiveness of the metal complex ink to the base material and the insulating layer is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The content of the resin in the metal complex ink is preferably 0.1% to 5% by mass with respect to the total mass of the metal complex ink.

### (Additive)

The metal complex ink may further include an additive as long as the coating properties or the electromagnetic wave shielding properties are not impaired.

Examples of the additive include an inorganic salt, an organic salt, an inorganic oxide such as silica, a surface modifier, a wetting agent, a crosslinking agent, an antioxidant, a rust inhibitor, a heat resistance stabilizer, a surfactant, a plasticizer, a curing agent, a thickener, and a silane coupling agent.

### <Metal Salt Ink>

The metal salt ink is, for example, a conductive ink obtained by dissolving a metal salt in a solvent.

It is preferable that the metal salt ink does not include the complexing agent.

### (Metal Salt)

The metal salt ink includes a metal salt.

Examples of the metal constituting the metal salt include silver, copper, gold, aluminum, magnesium, tungsten, molybdenum, zinc, nickel, iron, platinum, tin, copper, and lead. From the viewpoint of the conductivity, the metal constituting the metal salt preferably includes at least one selected from the group consisting of silver, gold, platinum, nickel, palladium, and copper, more preferably includes at least one of silver or copper, and still more preferably includes silver.

The content of the metal in the metal salt ink in terms of metal element is preferably 1% to 40% by mass, more preferably 5% to 30% by mass, and still more preferably 7% to 20% by mass with respect to the total mass of the metal salt ink.

From the viewpoint of the surface resistivity and the jetting stability, the content of the metal salt in the metal salt ink is preferably 10% to 90% by mass, and more preferably 10% to 40% by mass with respect to the total mass of the metal salt ink.

Examples of the metal salt include a benzoate, a halide, a carbonate, a citrate, an iodate, a nitrite, a nitrate, an acetate, a phosphate, a sulfate, a sulfide, a trifluoroacetate, and a carboxylate of a metal. Furthermore, two or more kinds of the salts may be combined.

From the viewpoint of the conductivity and the storage stability, the metal salt is preferably a metal carboxylate.

A carboxylic acid forming the metal carboxylate is preferably at least one selected from the group consisting of formic acid and a carboxylic acid having 1 to 30 carbon atoms, more preferably a carboxylic acid having 8 to 20 carbon atoms, and still more preferably a fatty acid having 8 to 20 carbon atoms. The fatty acid may be linear or branched, and may have a substituent.

The metal salt may be a commercially available product or may be produced by a known method. A silver salt is produced, for example, by the following method.

A silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time using an ultrasonic stirrer, and a precipitate thus generated is washed with ethanol and decanted. All of these steps can be performed at room temperature (25° C.). A mixing ratio of the silver compound to the formic acid or fatty acid having 1 to 30 carbon atoms in terms of the molar ratio is preferably 1:2 to 2:1, and more preferably 1:1.

### (Additive)

The metal salt ink may include additives such as a solvent, a reducing agent, and a resin.

Suitable aspects of the solvent, the reducing agent, and the resin are the same as those of the various components that can be included in the metal complex ink.

### EXAMPLES

Hereinbelow, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### [Curable Composition]

Each component included in the curable composition of the embodiment of the present invention and a method for preparing the curable composition will be described.

A mixture of various components at contents shown in Table 1 below was prepared and stirred under the conditions of 5,000 rpm for 20 minutes at 25° C. using a mixer (product name “L4R”, manufactured by Silverson) to obtain a curable composition of each Example and each Comparative Example.

Furthermore, the contents of various components in the table are in terms of parts by mass.

### [Cyclopolymerizable Monomer]

AOMA: Methyl α-(allyloxymethyl)acrylate (manufactured by Nippon Shokubai Co., Ltd.)
RHMA-D: Dimethyl-2,2′-[oxybis(methylene)]bisacrylate
RHMA-D was synthesized based on the procedure described in JP2015-172120A.

### [Thermally Crosslinking Group-Containing Monomer]

4HBAGE: 4-Hydroxybutyl acrylate glycidyl ether (manufactured by Shin-Nippon Kagaku Industry Co., Ltd.)
GMA: Glycidyl methacrylate
4HBA: 4-Hydroxybutyl acrylate

### [Polyfunctional Monomer]

HDDA: 1,6-Hexanediol diacrylate (product name “SR238”, manufactured by Sartomer Company Inc.)
PEGDA: Polyethylene glycol (400) diacrylate (manufactured by Sartomer Company Inc.)

### [Photopolymerization Initiator]

Omnirad 379: 2-(Dimethylamino)-2-(4-methylbenzyl)-1-(4-morpholinophenyl)-butan-1-one (manufactured by IGM Resins B. V.)
ITX: 2-Isopropylthioxanthone (product name “SPEEDCURE ITX” manufactured by Lambson Ltd.)
SC7010: Product name “SpeedCure 7010” (manufactured by Lambson)

### [Surface Modifier]

BYK-UV-3535: Modified polyether-based surface modifier (manufactured by BYK-Chemie, including neither a fluorine atom nor a silicon atom)
BYK-381: Acrylic surface modifier (manufactured by BYK-Chemie, including neither a fluorine atom nor a silicon atom)
F-554: Fluorine- and lipophilic group-containing oligomer (product name “MEGAFACE F-554”, manufactured by DIC Corporation)
BYK-307: Silicone-based surface modifier (manufactured by BYK-Chemie)

### [Polymerization Inhibitor]

MEHQ: p-Methoxyphenol (manufactured by FUJIFILM Wako Pure Chemical Corporation)

### [Thermally Crosslinking Agent]

E402-B80: Block isocyanate (manufactured by Asahi Kasei Corporation)

### [Other Components (Monofunctional Monomer)]

NVC: N-Vinyl-8-caprolactam (manufactured by FUJIFILM Wako Pure Chemical Corporation)
IBOA: Isobornyl acrylate (product name “SR506D”, manufactured by Sartomer Company Inc.)

### [Conductive Ink]

Silver neodecanoate (30 g) was added to a 200 mL three-neck flask. Next, terpineol (30 g) and xylene (40 g) were added thereto and the mixture was stirred to obtain a solution including a silver salt. The obtained solution was filtered using a polytetrafluoroethylene (PTFE) membrane filter having a pore diameter of 0.45 μm to obtain a conductive ink.

### [Manufacture of Laminate]

### [Preparation of Electronic Substrate]

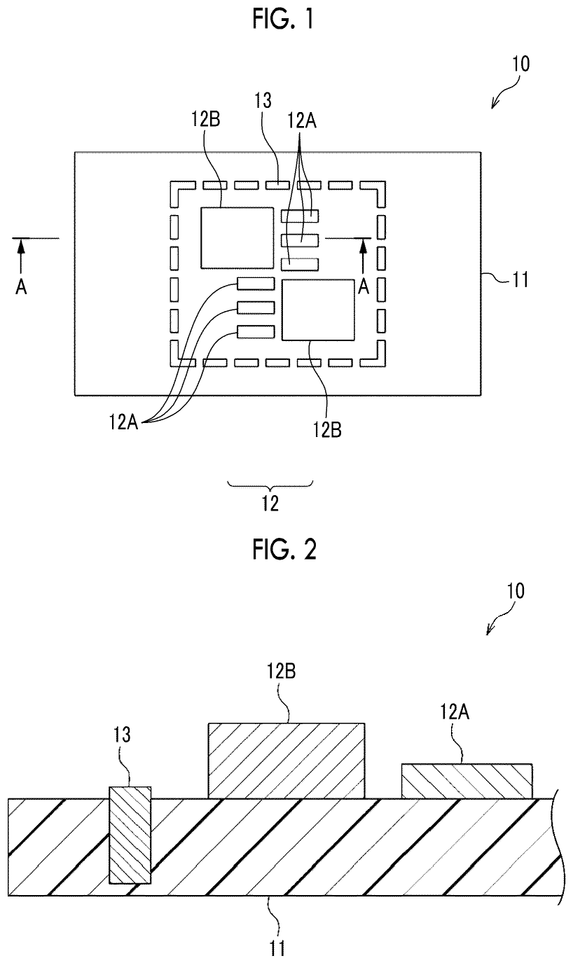

As an electronic substrate, an electronic substrate 10 shown in FIGS. 1 and 2 was prepared. Hereinafter, the dimensions of the electronic substrate 10 are shown.

A width of a ground electrode 13: 900 μm

A height of the ground electrode 13 (a height of a portion protruding onto a wiring board 11): 25 μm

A region surrounded by the ground electrode 13: 20 mm×18 mm

A height of an electronic component 12A: 200 μm

A height of the electronic component 12B: 500 μm

A distance between the electronic component 12B and the ground electrode: 200 μm

### [Formation of Insulating Layer]

An ink cartridge (10 picoliters) of an ink jet recording device (trade name “DMP-2850” manufactured by FUJIFILM Dimatix, Inc.) was filled with the curable composition prepared by the above-described method. As image recording conditions, the resolution was set to 1,270 dots per inch (dpi), and the jetting amount was set to 10 picoliters/dot.

Hereinafter, a step of applying the curable composition to a target range using an ink jet recording device and irradiating the curable composition with ultraviolet rays is defined as one cycle. The irradiation with ultraviolet rays was performed by using an ultraviolet irradiation device (product name “UV SPOT CURE OmniCure S2000” manufactured by Lumen Dynamics Group Inc.) installed next to the ink jet head. The illuminance of ultraviolet rays was set to 12 W/cm², the resolution and the frequency of the ink jet recording device were adjusted, and the exposure amount per cycle was set to 1.8 J/cm². In addition, the time from a time point at which the application of the curable composition was completed to a start of the irradiation with ultraviolet rays was set to 0.2 seconds.

In a region A where an electronic component 12A and an electronic component 12B in FIG. 1 were not disposed, the cycle was repeated twice. Next, the cycle was repeated three times in the region A, and the region B in FIG. 1 in which the electronic component 12A was disposed. Furthermore, the cycle was repeated twice in the region A, the region B, and a region C in FIG. 1 where the electronic component 12B was disposed.

In the laminate obtained as above, the maximum value of the thickness of the exposed curable composition with respect to a surface of the wiring board 11 was 700 μm. In addition, the thickness of the exposed curable composition with respect to a surface of the electronic component 12B was 200 μm.

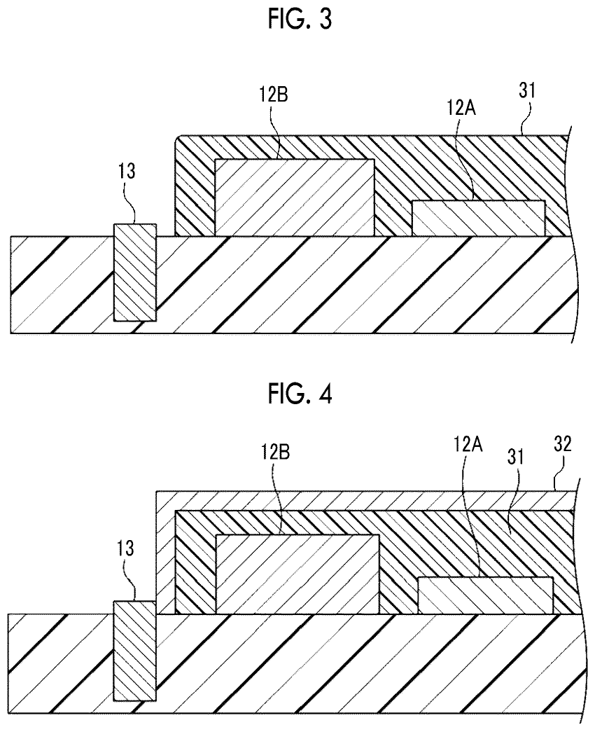

Thereafter, the electronic substrate on which the exposed curable composition had been laminated was heated on a hot plate at 150° C. for 1 hour to form an insulating layer. In this manner, a laminate shown in FIG. 3, comprising the insulating layer 31 on the electronic substrate 10, was obtained.

### [Formation of Conductive Layer]

An ink cartridge (10 picoliters) of an ink jet recording device (product name “DMP-2850”, manufactured by FUJIFILM Dimatix, Inc.) was filled with the conductive ink obtained by the above-described method. The image recording conditions were set to a resolution of 1,270 dpi and a liquid droplet volume of 10 picoliters per dot.

The electronic substrate 10 on which the insulating layer 31 was formed was preheated to 60° C. A cycle of applying the conductive ink onto the insulating layer 31 by the ink jet recording device and heating the conductive ink at 160° C. for 1 hour using an oven was repeated 8 times.

In this manner, a conductive layer having a metallic luster and a thickness of 3.2 μm was formed on the insulating layer 31.

By the steps above, the laminate shown in FIG. 4, comprising the electronic substrate 10, the insulating layer 31, and the conductive layer 32 in this order, was obtained.

### [Evaluation]

### [Adhesiveness]

The adhesiveness between the conductive layer and the insulating layer was evaluated in accordance with the following procedure.

After producing the laminate of each of Examples and Comparative Examples, the laminate was allowed to stand at 25° C. for 1 hour. Thereafter, a piece of tape of CELLOTAPE (registered trademark, No. 405, manufactured by Nichiban Co., Ltd., width: 12 mm, hereinafter also simply referred to as a “tape”) was attached onto the conductive layer of the laminate of each of Examples and Comparative Examples. Next, the tape piece was peeled off from the conductive layer to evaluate the adhesiveness between the conductive layer and the insulating layer. The tape was attached and peeled off by the following method.

The tape was unwound at a constant speed and cut in a length of about 20 mm to obtain a tape piece. A piece of the obtained tape was overlaid on the exposed conductive layer of the laminate of each of Examples and Comparative Examples, and a region having a width of 9 mm and a length of 9 mm in the center portion of the piece of the obtained tape was attached with a finger and rubbed firmly with a fingertip. After attaching the piece of tape, the piece of the tape was peeled off at an angle close to 60° over 0.5 to 1.0 second by grasping an end of the piece of tape.

The presence or absence of the attachment in the peeled piece of the tape, and the presence or absence of the peeling of the conductive layer in the laminate were visually observed. The adhesiveness between the conductive layer and the insulating layer was evaluated in accordance with the following evaluation standard.
A: No attachment was observed on the tape piece and no peeling of the conductive layer was observed.
B: Some attachment was found on the piece of tape and peeling of the conductive layer was not found; or no attachment was found on the piece of tape and some peeling of the conductive layer was found although the peeling was within an allowable range.
C: Adhesions were found on the piece of tape and most of the conductive layer was found to be peeled off, which are out of the allowable range.

### [Smoothness]

The surface roughness of the exposed conductive layer of the laminate of each of Examples and Comparative Examples was measured using a laser microscope (VK-X3000, manufactured by Keyence Corporation). From the value of an arithmetic average roughness Ra thus obtained, the smoothness of the conductive layer was evaluated in accordance with the following evaluation standard.
A: The arithmetic average roughness Ra was less than 20 μm.
B: The arithmetic average roughness Ra was 20 μm or more and less than 50 μm.
C: The arithmetic average roughness Ra was 50 μm or more and less than 80 μm.
D: The arithmetic average roughness Ra was 80 μm or more.

### [Crack Suppressibility]

According to the procedure of [Manufacture of Laminate] above, a laminate shown in FIG. 3, comprising an insulating layer 31 on the electronic substrate 10, was obtained.

The obtained laminate was placed in a small environment tester SH-242 (manufactured by ESPEC Corporation), and subjected to 100 cycles of heating and cooling from −40° C. to 100° C. at 2 cycles/h.

Thereafter, the appearance of the laminate was observed with a loupe, the number of locations where cracks had occurred in the insulator was counted, and the crack suppressibility was evaluated in accordance with the following evaluation standard.
A: 0 Locations
B: 1 Location
C: Two or more locations

### [Peelability]

The peelability between the insulating layer and the module was evaluated by the following procedure.

According to the procedure of [Manufacture of Laminate] above, a laminate shown in FIG. 3, comprising an insulating layer 31 on the electronic substrate 10, was obtained.

Thereafter, while heating the laminate to 120° C. using a hot plate, the insulating layer was peeled off from the electronic substrate in order from the four corners using tweezers, and the range where the insulating layer was peeled off was visually observed. The peelability was evaluated in accordance with the following evaluation standard from a proportion of the area from which the insulating layer was peeled off to the printing area.
A: 80% or more of the printing area
B: 50% or more and less than 80% of the printing area
C: Less than 50% of the printing area

### [Results]

The composition of the curable composition of each of Examples and Comparative Examples, and the evaluation results of the adhesiveness between the conductive layer and the insulating layer, and the smoothness of the conductive layer are shown in Table 1.

In addition, the evaluation results of the crack suppressibility and the peelability of each example are shown in Table 2.

In Table 2, the column of “A/B” shows the mass ratio of the content of the A) cyclopolymerizable monomer to the content of the B) thermally crosslinking group-containing monomer (content of cyclopolymerizable monomer/content of thermally crosslinking group-containing monomer).

In Table 2, the column of “A/C” shows the mass ratio of the content of the A) cyclopolymerizable monomer to the content of the C) polyfunctional monomer (content of cyclopolymerizable monomer/content of polyfunctional monomer).

| | A) Cyclopoly [symbol] able | | B) [symbol] crosslinking | | | C) Poly [symbol] | | | | Photopolymerization | | |
|---|---|---|---|---|---|---|---|---|---|---|---|---|
| | [symbol] | | group- [symbol] | | | [symbol] | | [symbol] | | inhibitor | | |
| | [symbol] | [symbol] | [symbol] | GMA | [symbol] | HDDA | PEGDA | NVC | [symbol] | [symbol] | ITX | [symbol] |
| Example 1 | [symbol] | | [symbol] | | | | [symbol] | | | [symbol] | [symbol] | |
| Example 2 | [symbol] | | [symbol] | | | | [symbol] | | | [symbol] | [symbol] | |
| Example 3 | [symbol] | | [symbol] | | | | [symbol] | | | [symbol] | [symbol] | |
| Example 4 | [symbol] | | [symbol] | | | | [symbol] | | | [symbol] | [symbol] | |
| Example 5 | [symbol] | [symbol] | [symbol] | | | | [symbol] | | | [symbol] | [symbol] | |
| Example 6 | | [symbol] | [symbol] | | | | [symbol] | | | [symbol] | [symbol] | |
| Example 7 | [symbol] | | [symbol] | | | | [symbol] | | | [symbol] | [symbol] | |
| Example 8 | [symbol] | | [symbol] | | | | [symbol] | | | [symbol] | [symbol] | |
| Example 9 | [symbol] | | [symbol] | | | | [symbol] | | | [symbol] | | [symbol] |
| Example 10 | [symbol] | | [symbol] | | | [symbol] | | | | [symbol] | | [symbol] |
| Example 11 | [symbol] | | [symbol] | | | | [symbol] | | | [symbol] | [symbol] | |
| Example 12 | [symbol] | | [symbol] | | | | [symbol] | | | [symbol] | [symbol] | |
| Example 13 | [symbol] | | [symbol] | | | | [symbol] | | | [symbol] | | [symbol] |
| Example 14 | [symbol] | | [symbol] | | | | [symbol] | | | [symbol] | [symbol] | |
| Example 15 | [symbol] | | | [symbol] | | | [symbol] | | | [symbol] | [symbol] | |
| Example 16 | [symbol] | | | | [symbol] | | [symbol] | | | [symbol] | [symbol] | |
| Example 17 | [symbol] | | [symbol] | | | | [symbol] | | | [symbol] | | [symbol] |
| Comparative Example 1 | [symbol] | | [symbol] | | | | | | [symbol] | [symbol] | [symbol] | |
| Comparative Example 2 | [symbol] | | | | | | [symbol] | [symbol] | | [symbol] | [symbol] | |
| Comparative Example 3 | [symbol] | | | | | | [symbol] | | | [symbol] | [symbol] | |
| Comparative Example 4 | | | [symbol] | | | | [symbol] | | | [symbol] | [symbol] | |
| Comparative Example 5 | | | | | | | [symbol] | | [symbol] | [symbol] | [symbol] | |
| Comparative Example 6 | | | | | | | [symbol] | | [symbol] | [symbol] | [symbol] | |
| Comparative Example 7 | [symbol] | | [symbol] | | | | [symbol] | | | [symbol] | | [symbol] |
| Comparative Example 8 | [symbol] | | [symbol] | | | | [symbol] | | | [symbol] | | [symbol] |

| | | | | | Polymerization | [symbol] | | |
|---|---|---|---|---|---|---|---|---|
| | Surface modifier | | | | [symbol] | crossling agent | | |
| | [symbol] | [symbol] | [symbol] | [symbol] | MEHQ | [symbol] | Adhesiveness | [symbol] |
| Example 1 | | [symbol] | | | [symbol] | | A | A |
| Example 2 | | [symbol] | | | [symbol] | | B | B |
| Example 3 | | [symbol] | | | [symbol] | | B | B |
| Example 4 | | [symbol] | | | [symbol] | | B | B |
| Example 5 | | [symbol] | | | [symbol] | | A | B |
| Example 6 | | [symbol] | | | [symbol] | | A | B |
| Example 7 | | [symbol] | | | [symbol] | | B | B |
| Example 8 | [symbol] | | | | [symbol] | | A | A |
| Example 9 | [symbol] | | | | [symbol] | | A | A |
| Example 10 | [symbol] | | | | [symbol] | | A | A |
| Example 11 | | [symbol] | | | [symbol] | | B | A |
| Example 12 | | [symbol] | | | [symbol] | | A | B |
| Example 13 | | [symbol] | | | [symbol] | | B | A |
| Example 14 | | [symbol] | | | [symbol] | | B | A |
| Example 15 | | [symbol] | | | [symbol] | | B | A |
| Example 16 | | [symbol] | | | [symbol] | [symbol] | B | B |
| Example 17 | | [symbol] | | | [symbol] | | A | A |
| Comparative Example 1 | | [symbol] | | | [symbol] | | B | C |
| Comparative Example 2 | | [symbol] | | | [symbol] | | C | B |
| Comparative Example 3 | | [symbol] | | | [symbol] | | C | B |
| Comparative Example 4 | | [symbol] | | | [symbol] | | C | C |
| Comparative Example 5 | | [symbol] | | | [symbol] | | C | C |
| Comparative Example 6 | | [symbol] | | | [symbol] | | A | C |
| Comparative Example 7 | | | [symbol] | | [symbol] | | C | C |
| Comparative Example 8 | | | | [symbol] | [symbol] | | B | B |

[symbol]

indicates data missing or illegible when filed

TABLE 2

| | | | Crack | |
|---|---|---|---|---|
| | A/B | A/C | suppressibility | Peelability |
| Example 1 | 27.5 | 1.7 | A | A |
| Example 2 | 10.4 | 1.6 | A | B |
| Example 3 | 1.8 | 1.1 | A | B |
| Example 4 | 2.6 | 2.9 | A | B |
| Example 5 | 27.5 | 1.7 | B | A |
| Example 6 | 27.5 | 1.7 | B | B |
| Example 7 | 27.5 | 1.7 | A | B |
| Example 8 | 27.5 | 1.7 | A | A |
| Example 9 | 27.5 | 1.7 | A | A |
| Example 10 | 27.5 | 1.7 | A | A |
| Example 11 | 16.5 | 0.6 | A | A |
| Example 12 | 40.0 | 10.1 | B | B |
| Example 13 | 4.0 | 0.1 | A | B |
| Example 14 | 112.8 | 1.7 | B | B |
| Example 15 | 27.5 | 1.7 | B | B |
| Example 16 | 25.0 | 1.8 | B | B |
| Example 17 | 27.5 | 1.7 | A | A |

From the results shown in Table 1, it was confirmed that the curable composition of the embodiment of the present invention has more excellent effects than the curable compositions of Comparative Examples 1 to 8 which do not include at least one of a cyclopolymerizable monomer, a thermally crosslinking group-containing monomer, a polyfunctional monomer, or a surface modifier including neither a fluorine atom nor a silicon atom.

It was confirmed that in a case where the cyclopolymerizable monomer includes AOMA, the peelability is more excellent, and in a case where the cyclopolymerizable monomer is AOMA, the smoothness and the crack suppressibility of the conductive layer are more excellent (comparison of Examples 1, 5, and 6).

It was confirmed that in a case where the content of the thermally crosslinking group-containing monomer is 0.5% by mass or more and less than 5.0% by mass with respect to the total mass of the curable composition, the effects of the present invention and the peelability are more excellent (comparison of Examples 1 to 4 and 14).

It was confirmed that in a case where the thermally crosslinking group-containing monomer is a compound represented by Formula (B2), the smoothness of the conductive layer is more excellent, and in a case where the thermally crosslinking group-containing monomer is a compound represented by Formula (B2) having two or more carbon atoms in R³, the adhesiveness between the conductive layer and the insulating layer, the crack suppressibility, and the peelability are more excellent (comparison of Examples 1, 15, and 16).

It was confirmed that in a case where the mass ratio of the content of the cyclopolymerizable monomer to the content of the thermally crosslinking group-containing monomer is 5.0 to 40.0, the effects of the present invention and the peelability are excellent (comparison of Examples 1, 3, 4, 13, and 14).

It was confirmed that in a case where the mass ratio of the content of the cyclopolymerizable monomer to the content of the polyfunctional monomer is 1.0 or more, the adhesiveness between the conductive layer and the insulating layer is more excellent. In addition, it was confirmed that in a case where the mass ratio of the content of the cyclopolymerizable monomer to the content of the polyfunctional monomer is 7.0 or less, the smoothness, the crack suppressibility, and the peelability of the conductive layer are more excellent (comparison of Examples 1, 11, and 12).

It was confirmed that in a case where the mass ratio of the content of the alkylphenone compound to the content of the thioxanthone compound is 1.5 or less, the effects of the present invention and the peelability are more excellent (comparison of Examples 1 and 7).

### EXPLANATION OF REFERENCES

10: electronic substrate
11: wiring board
12, 12A, 12B: electronic component
13: ground electrode
31: insulating layer
32: conductive layer

What is claimed is:

1. A curable composition for forming an insulating layer adjacent to a conductive layer, the curable composition comprising:
a cyclopolymerizable monomer;
a thermally crosslinking group-containing monomer;
a polyfunctional monomer;
a photopolymerization initiator; and
a surface modifier including neither a fluorine atom nor a silicon atom.

2. The curable composition according to claim 1,
wherein a mass ratio of a content of the cyclopolymerizable monomer to a content of the thermally crosslinking group-containing monomer is 5.0 to 40.0, and
a mass ratio of the content of the cyclopolymerizable monomer to a content of the polyfunctional monomer is 1.0 to 7.0.

3. The curable composition according to claim 1,
wherein the cyclopolymerizable monomer is methyl α-allyloxymethyl acrylate.

4. The curable composition according to claim 1,
wherein a content of the thermally crosslinking group-containing monomer is 0.5% by mass or more and less than 5.0% by mass with respect to a total mass of the curable composition.

5. The curable composition according to claim 1,
wherein the thermally crosslinking group-containing monomer is a compound represented by Formula (B2), 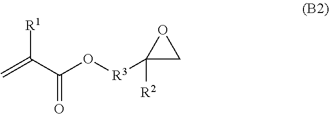
in Formula (B2), R¹ and R² each independently represent a hydrogen atom or an alkyl group, and
R³ represents an alkylene group which may have an ether bond.

6. The curable composition according to claim 1,
wherein the conductive layer has silver or copper.

7. A laminate comprising:
a conductive layer; and
an insulating layer formed of the curable composition according to claim 1.

8. The laminate according to claim 7,
wherein the laminate is used as an electromagnetic wave shield disposed on a printed wiring board.

9. A method for producing a laminate, the method comprising:
a step 1 of forming an insulating layer by an ink jet recording method using the curable composition according to claim 1; and
a step 2 of forming a conductive layer on the insulating layer, using a conductive ink.

10. The method for producing a laminate according to claim 9,
wherein the step 1 includes a step of irradiating a coating film of the curable composition with active energy rays and then heating the coating film.

11. The curable composition according to claim 2,
wherein the cyclopolymerizable monomer is methyl α-allyloxymethyl acrylate.

12. The curable composition according to claim 2,
wherein a content of the thermally crosslinking group-containing monomer is 0.5% by mass or more and less than 5.0% by mass with respect to a total mass of the curable composition.

13. The curable composition according to claim 2,
wherein the thermally crosslinking group-containing monomer is a compound represented by Formula (B2), 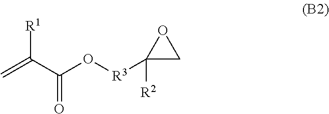
in Formula (B2), R¹ and R² each independently represent a hydrogen atom or an alkyl group, and
R³ represents an alkylene group which may have an ether bond.

14. The curable composition according to claim 2,
wherein the conductive layer has silver or copper.

15. A laminate comprising:
a conductive layer; and
an insulating layer formed of the curable composition according to claim 2.

16. The laminate according to claim 15,
wherein the laminate is used as an electromagnetic wave shield disposed on a printed wiring board.

17. A method for producing a laminate, the method comprising:
a step 1 of forming an insulating layer by an ink jet recording method using the curable composition according to claim 2; and
a step 2 of forming a conductive layer on the insulating layer, using a conductive ink.

18. The method for producing a laminate according to claim 17,
wherein the step 1 includes a step of irradiating a coating film of the curable composition with active energy rays and then heating the coating film.

19. The curable composition according to claim 3,
wherein a content of the thermally crosslinking group-containing monomer is 0.5% by mass or more and less than 5.0% by mass with respect to a total mass of the curable composition.

20. The curable composition according to claim 3,
wherein the thermally crosslinking group-containing monomer is a compound represented by Formula (B2), 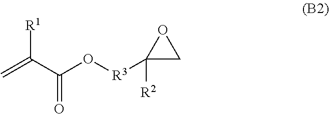
in Formula (B2), R¹ and R² each independently represent a hydrogen atom or an alkyl group, and
R³ represents an alkylene group which may have an ether bond.
